(19) United States
(12) Patent Application Publication
(10) Pub. No.: US 2014/0148596 A1
(43) Pub. Date: May 29, 2014

(54) Covalent Organic Frameworks and Methods of Making Same

(71) Applicants: William R. Dichtel, Ithaca, NY (US); Eric L. Spitler, Monroeville, PA (US)

(72) Inventors: William R. Dichtel, Ithaca, NY (US); Eric L. Spitler, Monroeville, PA (US)

(73) Assignee: CORNELL UNIVERSITY, Ithaca, NY (US)

(21) Appl. No.: 13/639,164

(22) PCT Filed: Apr. 7, 2011
(86) PCT No.: PCT/US11/31603

§ 371 Date: Jan. 21, 2014

Related U.S. Application Data
(60) Provisional application No. 61/321,649, filed on Apr. 7, 2010.

(51) Int. Cl. H01L 51/00

(52) U.S. Cl. CPC H01L 51/0078; H01L 51/0092
USPC 540/465; 540/472

(57) ABSTRACT

Crystalline COFs comprising a phthalocyanine moiety and a boron-containing multifunctional linking group joined by boronate ester bonds. A method for making crystalline COFs comprising Lewis acid catalyzed formation of boronate ester bonds between protected catechol subunits and multifunctional linkers comprising boronic acid groups. The COFs can be used in applications such as, for example, electronic devices.

### CROSS-REFERENCE TO RELATED APPLICATIONS

This application claims priority to U.S. provisional patent application No. 61/321,649, filed Apr. 7, 2010, the disclosure of which is incorporated herein by reference.

### STATEMENT REGARDING FEDERALLY SPONSORED RESEARCH

This invention was made with government support under CHE-0847926 and CHE-0936988 awarded by the National Science Foundation. The government has certain rights in the invention.

### FIELD OF THE INVENTION

The present invention generally relates to covalent organic frameworks, methods of making such frameworks, uses of such frameworks, materials comprising such frameworks, and devices comprising such frameworks.

### BACKGROUND OF THE INVENTION

The continuing development of organic semiconductors will bring about flexible displays, radio frequency identification (RFID) tags, improved lighting technologies, efficient sensors, and economically competitive solar cells. In addition to their low cost, one of the most attractive aspects of organic electronic materials is the promise of tuning device properties through rational chemical design and synthesis. Known structure-property relationships and computational tools enable predictable tuning of the bandgaps and HOMO and LUMO energies of organic semiconductors. However, control of the packing and long-range order is also critical for efficient charge transport through the material. Efforts in crystal engineering have produced examples of cofacially-packed pentacene and tetrathiafulvalene derivatives, but reliably predicting the crystal structures of small organic molecules remains an unsolved challenge. Varying the identity or positions of substituents to tune electronic properties can induce unpredictable changes in long-range order, limiting the generality of molecular design strategies.

Despite their great promise, the limited generality of synthetic methods for COFs represents a significant roadblock to fully realizing their potential. In previous reports, boronate ester-linked COFs have been synthesized through the solvothermal condensation of polyfunctional boronic acids and catechols. However, only 2,3,6,7,10,11 hexahydroxytriphenylene (HHTP) and four 1,2,4,5-tetrahydroxybenezene derivatives have produced crystalline materials, and HHTP is the only building block used more than once. Reports of new boronate ester-linked COFs have ceased after an initial flurry of activity. This lack of progress is attributable to undesirable features of compounds containing multiple catechol moieties. Polyfunctional catechols are prone to oxidation and are often sparingly soluble in organic solvents, factors that hinder both the preparation of useful quantities of functionalized monomers and their incorporation into COFs.

### BRIEF SUMMARY OF THE INVENTION

In an aspect, the present invention provides a crystalline covalent organic framework (COF) comprising a plurality of phthalocyanine catechol subunits comprising a phthalocyanine moiety and at least two catechol moieties, and a plurality of multifunctional linker groups comprising boron, wherein a plurality of distinct phthalocyanaine catechol subunits are bonded to at least one multifunctional linker by boronate ester bonds. In an embodiment, the phthalocyanine catechol subunit. In an embodiment, the phthalocyanine subunit comprises a metal atom or metal ion.

In an embodiment, the framework has pores, having a diameter of 2 nm to 6 nm, wherein the pores run parallel to the stacked aromatic moieties. In an embodiment, the framework is a crystallite, where the longest dimension of the crystallite is from 50 nm to 10 microns. In an embodiment, the framework is thermally stable at temperatures of from 20° C. to 500° C. In an embodiment, the framework absorbs light having a wavelength of 200 nm to 1500 nm.

In an aspect, the present invention provides a method for making a crystalline organic framework comprising combining a protected subunit compound, a multifunctional linker comprising at least two boronic acid moieties, a Lewis acid, and a solvent at a suitable reaction temperature, where at least a plurality of covalent bonds are formed between at least one multifunctional linking compound and at least two different subunit compounds forming a two-dimensional or three-dimensional crystalline organic framework. In an embodiment, the Lewis acid is BF₃*Et₂O.

In an aspect, the present invention provides a device selected from solar cells, flexible displays, lighting devices, RFID tags, sensors, photoreceptors, batteries, capacitors, gas storage devices, gas separation devices, comprising a crystalline covalent organic framework described herein.

### BRIEF DESCRIPTION OF THE DRAWINGS

FIG. 1. BF₃.OEt₂ catalyzes the formation of 2-phenyl-1,3,2-benzodioxaborole from catechol acetonide (1) and phenylboronic acid (2). The partial ¹H-NMR spectra (300 MHz, 298K, CDCl₃) of the reaction mixture before and 18 hours after the addition of BF₃.OEt₂ show clean conversion of 1 and 2 to the corresponding boronic ester. No resonances corresponding to free catechol were observed in spectra taken at intermediate conversion.

FIG. 2. Synthesis and crystal lattice superstructure of Pc-PBBA COF. a, The Lewis acid-catalyzed deprotection/condensation protocol was used to form this COF from PBBA and the phthalocyanine tetraacetonide 3. b, Pc-PBBA COF exhibits a square lattice whose 2D sheets form eclipsed stacks.

FIG. 3. Experimental and simulated PXRD patterns and calculated unit cell parameters of Pc-PBBA COF, along with a comparison to an alternative staggered architecture. A, The experimental powder x-ray diffraction pattern (major observed reflections are labeled) overlaid with Pawley refined pattern of Pc-PBBA COF. B, A difference plot between the experimental and refined diffraction patterns shows excellent agreement. C, A simulated PXRD pattern for a Pc-PBBA COF square lattice shows good agreement with the experimental and refined patterns. D, A simulated PXRD for a theoretical 2D staggered structure, G, does not agree with the experimental and refined patterns. E & F, The crystal parameters extracted from the Pawley-refined PXRD are displayed on a model of the Pc-PBBA lattice.

FIG. 4. SEM images of Pc-PBBA COF. Two crystal morphologies were observed. They include (left) rectangular prisms ca. 1 μm in length and (right) flat sheets 2-4 μm in size.

FIG. 5. N₂ adsorption isotherm and Langmuir surface area plot. The isotherm indicates reversible nitrogen uptake with a small hysteresis at about P/P₀=0.5 (P₀=1 atm). The linear portion of the plot between 0.02 and 0.06 was used to calculate a Langmuir surface area of 506 m²/g (inset).

FIG. 6. Solution and solid state UV-Vis-NIR absorption spectra. FIG. 6b. Solid-state absorption spectra of phthalocyanine acetonide 3 and Pc-PBBA COF as powders using a praying mantis diffuse reflectance accessory (5 wt. % in potassium iodide background). Blue-shifts of the absorption maxima of solid phthalocyanine acetonide 3 and the Pc-PBBA COF (FIG. 6b) relative to solutions of 3 (FIG. 6a) are indicative of vertical 3. phthalocyanine stacking. Pc-PBBA COF absorbs strongly over a broad range of the visible and NIR region.

FIG. 7. Solid state emission spectra. The phthalocyanine tetraacetonide 3 (blue) exhibits a weak emission around 820 nm in the solid state. The COF (red) is non-emissive, as is expected for phthalocyanine H-aggregates.

FIG. 8. Example of COF formation.

FIG. 9 (Scheme S1). Synthesis of phthalonitrile acetonide 5.

FIG. 10 (Scheme S2). Synthesis of phthalocyanine acetonide 3.

FIG. 11 (Scheme S3) Deprotection of 3.

FIG. 12 (Scheme S4) Synthesis of Pc-PBBA COF.

FIG. 13. MALDI-MS spectrum of phthalocyanine acetonide 3.

FIG. 14. MALDI-MS spectrum of crude octahydroxyphthalocyanine.

FIG. 15. FT-IR spectra of (a) phthalocyanine acetonide 3, (b) 1,4-phenylenebisboronic acid, (c) crude octahydroxyphthalocyanine and (d) Pc-PBBA COF.

FIG. 16. FT-IR spectra of Pc-PBBA COF and starting materials overlayed.

FIG. 17. FT-IR of Pc-PBBA COF in the 650-2000 cm⁻¹ region with major peak groups assigned.

FIG. 18. Alternative staggered Pc-PBBA COF architecture.

FIG. 19. Experimental PXRD of Pc-PBBA COF (top) vs predicted eclipsed (middle) and staggered (bottom, see FIG. 18 for structure) packing models.

FIG. 20. Observed (black) vs. refined (red) PXRD pattern of Pc-PBBA COF and difference plot (blue, observed-refined).

FIG. 21 (Figure S9). PXRD pattern of phthalocyanine acetonide 3.

FIG. 22 (Figure S10). Thermogravimetric traces of Pc-PBBA COF and starting materials individually and as a mixture.

FIG. 23. (Figure S11). TGA traces of two samples of Pc-PBBA COF of differing crystalline quality (inset).

FIG. 24. Langmuir surface area plot calculated from isotherm data.

FIG. 25. BET surface area plot calculated from isotherm data.

FIG. 26. BJH pore width distribution plots vs. pore area (26a) and volume (26b) for Pc-PBBA COF calculated from isotherm data.

FIG. 27. Absorption spectrum of phthalocyanine acetonide 3, 2.1 μM in CH₂Cl₂ and excitation spectrum (arbitrary units). λ_{cm}=700 nm.

FIG. 28. Emission spectrum of phthalocyanine acetonide 3 in CH₂Cl₂. λₑₓ=422 nm.

FIG. 29. Solid-state excitation spectrum of phthalocyanine acetonide 3 powder using front-face detection. λₑₘ=820 nm. Off-scale peak at 410 nm is from emission from doubling of the excitation wavelength. Small, jagged peaks between 440 and 500 nm are characteristic features of the instrument lamp intensity.

FIG. 30. Characterization of COF-5 and COF-10 Prepared Using BF₃OEt₂ catalysis.

FIG. 31. Powder X-ray diffraction and FT-IR spectra (insets) of (a) COF-5 and (b) COF-10 prepared by the condensation of PBBA (COF-5) or 4,4′-biphenylenebis(boronic acid) (COF-10) with 2,3,6,7,10,11-hexahydroxytriphenylene tris(acetonide) in the presence of BF₃.OEt₂:

FIG. 32. Examples of COFs.

FIG. 33. Examples of preparation of COFs.

### DETAILED DESCRIPTION OF THE INVENTION

The present invention provides covalent organic frameworks (COFs), methods of making covalent organic frameworks, and uses thereof. The present invention also provides materials and devices comprising covalent organic frameworks. Such frameworks provide materials which have properties that make them useful for applications such as, for example, incorporation in electronic devices.

The present invention provides a new Lewis acid-catalyzed protocol for forming boronic esters directly from, for example, protected catechols and arylboronic acids. This method addresses the limitations of previous methods such as, for example, oxidation of and poor solubility of the catechols. This transformation also provides crystalline boronate ester-linked COFs from, for example, protected polyfunctional catechols and bis(boronic acids). For example, using this method, a COF featuring a square lattice comprised of phthalocyanine macrocycles joined by phenylene bis(boronic acid) linkers was prepared. The phthalocyanines stack in an eclipsed fashion within the COF, forming 2.3 nm-wide pores that run parallel to the stacked chromophores. The material's broad absorbance over the solar spectrum, potential for efficient charge transport through the stacked phthalocyanines, good thermal stability, and the modular nature of COF synthesis make them suitable for applications in organic photovoltaic devices.

Covalent organic frameworks offer a new strategy for assembling organic semiconductors into robust networks with atomic precision and long-range order. COFs incorporate organic subunits into periodic two- and three-dimensional porous crystalline structures held together by covalent bonds rather than noncovalent interactions. These linkages provide robust materials with precise and predictable control over composition, topology, and porosity. The relative geometries of the reactive groups in the starting materials determine the COF's topology, which does not change significantly as other functional groups are varied. Two-dimensional COFs can assemble functional aromatic systems into cofacially-stacked morphologies ideal for transporting excitons or charge carriers through the material. The boronate ester-linked materials are particularly promising for organic electronics in part because they incorporate two distinct molecular components, allowing their composition and porosity to be varied independently.

In an aspect, the present invention provides covalent organic frameworks. The COFs comprise at least two catechol subunits and at least one multifunctional linking group (MFLG), where at least one linking group is bonded to at least two distinct (e.g., adjacent) subunits. In an embodiment, the present invention provides a crystalline covalent organic framework (COF) comprising a plurality of phthalocyanine catechol subunits comprising a phthalocyanine moiety and at least two catechol moieties and a plurality of multifunctional linker groups comprising boron, where a plurality of distinct phthalocyanaine catechol subunits are bonded to at least one multifunctional linker by boronate ester bonds.

In an embodiment, each of the catechol moieties of each of the subunits is bonded to multifunctional linking groups. In an embodiment, the at least one multifunctional linking group comprises a boron-containing group and is bonded to at least two distinct subunits by boronate ester bonds. In an embodiment, the catechol subunit comprises a phthalocyanine group.

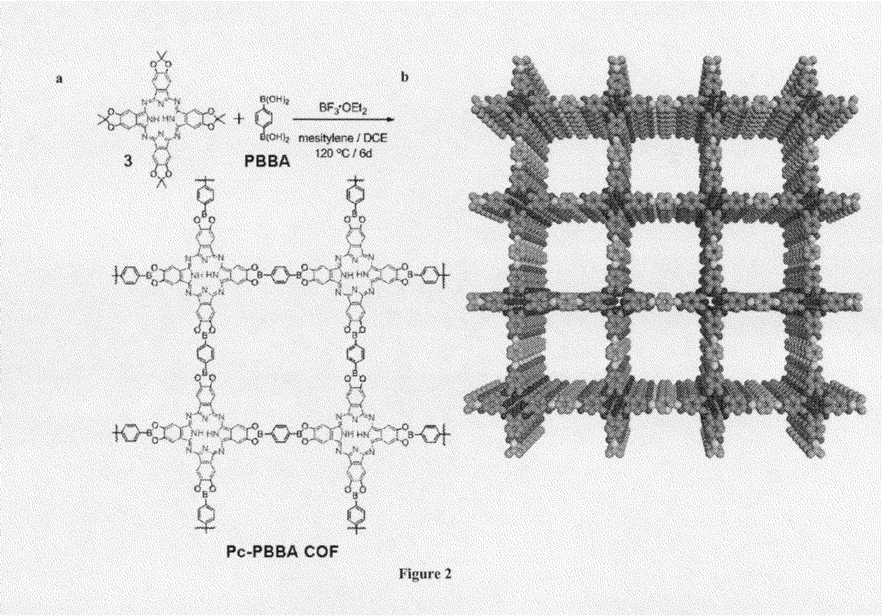

Examples of COFs are described in Examples 1 and 2. In an embodiment, the COFs comprise co-facially stacked aromatic moieties. Examples of such COFs are shown in FIGS. 2,3,8, and 32. An example of a COF is shown in the following generic COF structure:

-[MFLG]-[CATECHOL SUBUNIT]-[MFLG]-[CATECHOL SUBUNIT]-[MFLG]-

The catechol subunit comprises an aryl moiety and at least two catechol moieties. The aryl moiety comprises at least one conjugated moiety; where a plurality of the atoms of the aryl moiety is conjugated (e.g., form a conjugated it system). The aryl moiety can, for example, comprise an aromatic cyclic hydrocarbon, aromatic cyclic heterocycle, or a hydrocarbon or heteroatom-containing macrocycle. The aryl moiety and catechol moieties of a subunit can be distinct (i.e., separate) structures or can have common atoms (i.e., share structural elements) within the catechol subunit. In an embodiment, the catechol subunit comprises 2 to 6 catechol moieties. In an embodiment, the aryl moiety is a phthalocyanine. An example of a catechol subunit is an unsubstituted phthalocyanine catechol subunit having the following structure:

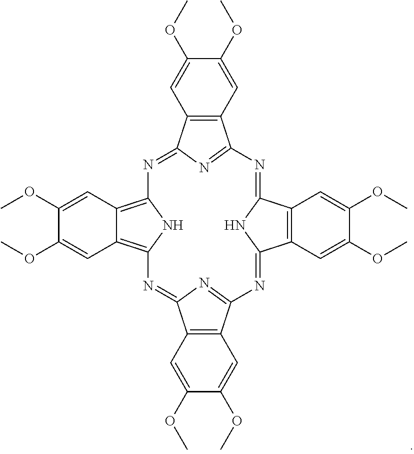

The catechol subunits may be substituted or unsubstituted.

In an embodiment, the catechol subunit comprises a metal (e.g., a metal atom or a metal ion). The metal is chemically bonded to the subunit. It is expected that any metal atom or metal ion can be incorporated in a catechol subunit (e.g., phthalocyanine catechol subunit). Examples of suitable metals include, but are not limited to, Zn, Ni, Cu, Co, Lu, Tc, Tb, and the like.

In an embodiment, the catechol subunit is a substituted or unsubstituted phthalocyanine subunit. In this embodiment, the substituted or unsubstituted phthalocyanine subunit, where the phthalocyanine moiety is present as a free base or as an anion (e.g., a dianion), can further comprise a metal. An example of an unsubstituted phthalocyanine subunit comprising a metal ion is shown in the following structure:

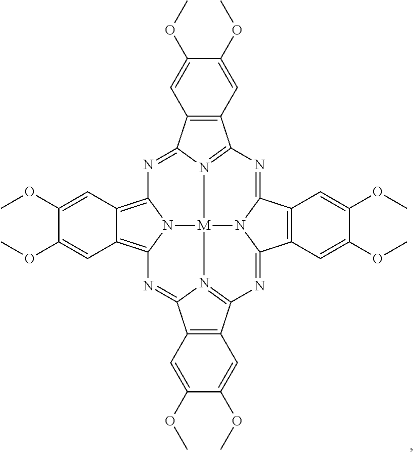

where M is a metal atom or metal ion.

The multifunctional linking group comprises boron and joins at least two catechol subunits via covalent bond (e.g., boronate ester bonds) between the subunits and the linking group. It is desirable that the multifunctional linking group be rigid such that covalent bonds between the subunits and multifunctional linking groups have the appropriate geometry resulting in a crystalline structure. The multifunctional linking group can comprise any group with a rigid structure such as, for example, an aryl group, a non-aromatic polycyclic group (e.g., an adamantane group) and the like. A multifunctional linking group can be, for example, formed from a multifunctional linker. In an embodiment, the multifunctional linking group is a bifunctional linking group with the following structure:

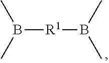

where R¹ is a substituted or unsubstituted aryl group comprising 5 to 50 carbons, including all integer number of carbons and ranges of number of carbons therebetween. The aryl moiety comprises at least one conjugated moiety, which comprises a number of atoms which are conjugated (e.g., form a conjugated n system). The aryl moiety can, for example, comprise an aromatic cyclic hydrocarbon, aromatic cyclic heterocycle, or a hydrocarbon or heteroatom-containing macrocycle. Examples of multifunctional linking groups include, but are not limited to, the following structures:

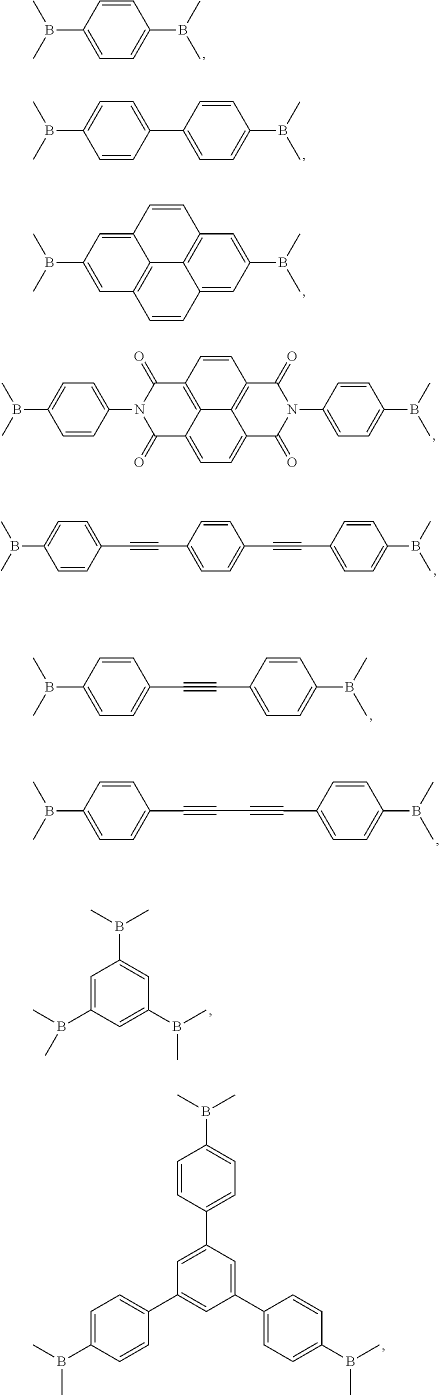

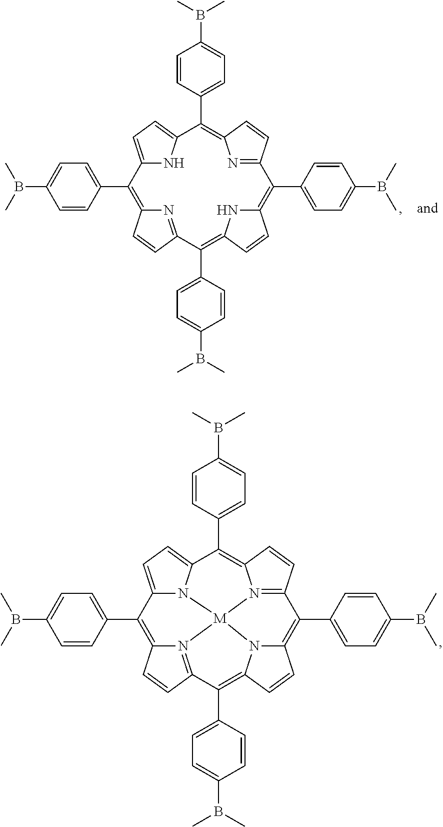

where M is metal atom or metal ion, and the like. In an embodiment, the multifunctional linking group comprises a metal (e.g., metal atom or a metal ion). The metal is chemically bonded to the multifunctional linking group. It is expected that any metal atom or metal ion can be incorporated in a multifunctional linking group. Examples of suitable metals include, but are not limited to, Zn, Ni, Cu, Co, Lu, Tc, Tb, and the like.

The COFs are crystalline. For example, the COFs can form crystallites (i.e., discrete structures) where the longest dimension of the crystallites can be from 50 nm to 10 microns, including all values to the nanometer and ranges of nanometers therebetween. In various embodiments, the COF comprise at least 2 unit cells, at least 5 unit cells, and at least 10 unit cells.

The COF have a porous (e.g., microporous (pores with a longest dimension of less than 2 nm) or mesoporous structure (pores with a longest dimension of 2 nm to 50 nm). The porous structure forms a repeating pattern (i.e., not a random distribution of pores) based at least in part on the structure of the catechol subunit and linker that make up the COF. In an embodiment, the framework has pores, where the pores run parallel to the stacked aromatic moieties. In an embodiment, the pores have a longest dimension (e.g., a diameter) of from 2 nm to 6 nm, including all values to the 0.05 nm and ranges to the 0.1 nm therebetween. In one example, the pores are 2.3 nm in diameter.

The COFs can have high surface area. For examples, the COFs can have a surface area 500 m²/g to 2500 m²/g, including all values to the m²/g and ranges of surface area therebetween. The surface area of the COFs can be determined by methods known in the art, for example, by BET analysis of gas (e.g., nitrogen) adsorption isotherms.

The COFs can exhibit desirable properties. For example, COFs can absorb light having a wavelength of from 200 nm to 1500 nm, including all values to the nanometer and ranges of nanometers therebetween. As another example, COFs can be semiconductors (e.g., exhibit semiconducting properties). As another example, COFs are thermally stable at temperatures of from 20° C. to 500° C., including all values to the degree Celsius and ranges of degrees Celsius therebetween.

In an aspect, the present invention provides a method for making COFs as described herein. In an embodiment, the method comprises combining a protected subunit, a multifunctional linker, a Lewis acid, and a solvent at a suitable reaction temperature, where at least a plurality of covalent bonds (e.g., boronate ester bonds) are formed between at least one multifunctional linking compound and at least two different subunit compounds forming a two-dimensional or three-dimensional crystalline organic framework. In an embodiment, in the COF each of the catechol moieties of each of the subunits is bonded to multifunctional linkers. The method can be carried out in the presence of moisture and oxygen. In an embodiment, the present invention provides crystalline organic frameworks made by the methods described herein.

A protected catechol subunit is a catechol subunit where at least one of the catechol groups of the subunit has a protecting group covalently bonded to it. In an embodiment, each catechol group has a protecting group covalently bonded to it. In another embodiment, two catechol groups are protected by a single protecting group (e.g., an acetal such as an acetonide group which can be formed from acetone.) Without intending to be bound by any particular theory, it is considered that the protecting group reduces the reactivity of the catechol group (e.g., the oxidative reactivity of the catechol group) and/or increases the solubility of the protected subunit relative to the unprotected subunit. An example of a protecting group is an acetal such as acetonide, benzylidene acetal, methoxymethyl, and dioxolane groups, and the like. Examples of protected subunits include, but are not limited to, the following structures:

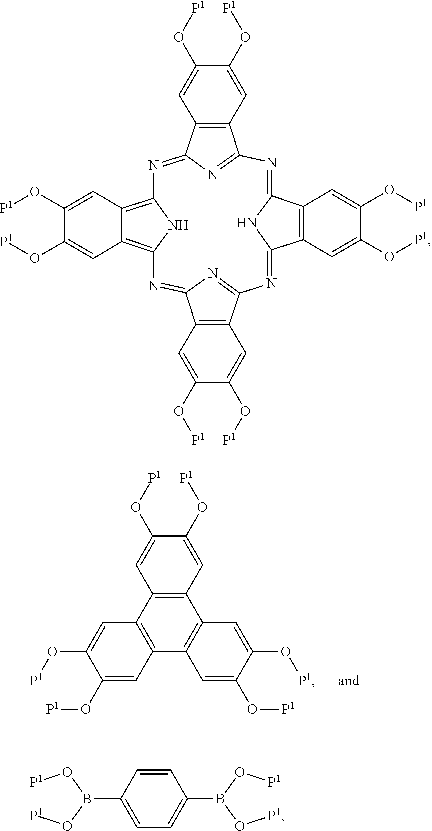

where P¹ is a protecting group. In an example, two P¹ groups are covalently bonded together and form a protecting group (e.g., an acetal such as an acetonide group). In an embodiment, the protected subunit has acetonide protecting groups and has the following structure:

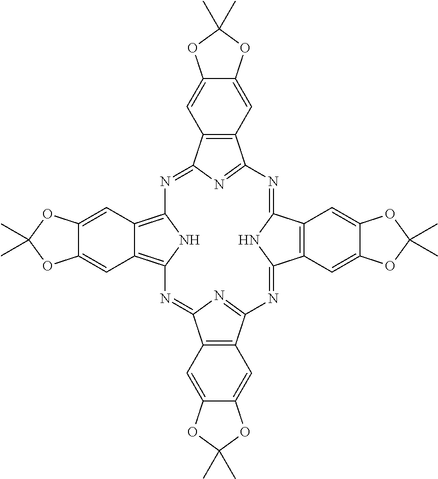

In an embodiment, the protected catechol subunit comprises a metal (e.g., metal atom or a metal ion). The metal is chemically bonded to the subunit. Examples of suitable metals include, but are not limited to, Zn, Ni, Cu, Co, Lu, Tc, Tb, and the like.

A multifunctional linker is a compound comprising a substituted or unsubstituted aryl moiety and has at least one boronic acid group that can react with a protected subunit to form at least one boronate ester bond. The aryl moiety comprises at least one conjugated moiety, a number of atoms which are conjugated (e.g., form a conjugated it system). The aryl moiety can, for example, comprise an aromatic cyclic hydrocarbon, aromatic cyclic heterocycle, or a hydrocarbon or heteroatom-containing macrocycle. In an embodiment, the multifunctional linker is a compound with two boronic acid groups. In an embodiment, the multifunctional linker has the following formula:

H—O—B—R¹—B—O—H

wherein R¹ is an aryl group or a polycyclic non-aromatic group (e.g., an adamantane group). In an embodiment, the boronic acid group reacts with adjacent catechol groups on a subunit to form a boronate ester bond. It is desirable that the multifunctional linker be rigid such that covalent bonds formed between the subunits and multifunctional linking groups have the appropriate geometry resulting in a crystalline structure. The multifunctional linker can comprise any group with a rigid structure such as, for example, an aryl group, a non-aromatic polycyclic group (e.g., an adamantane group) and the like.

Examples of multifunctional linkers include, but are not limited to, the following compounds:

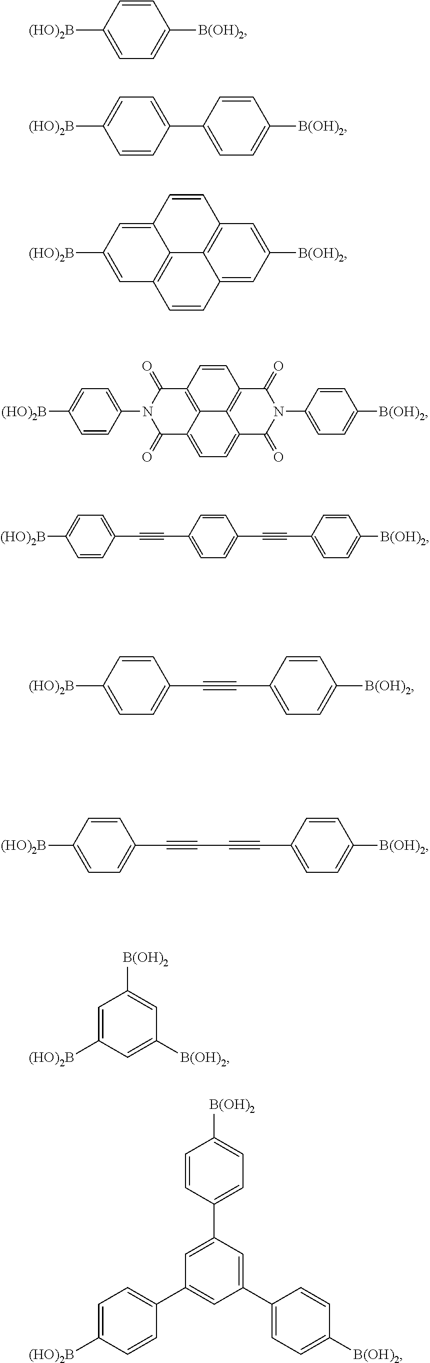

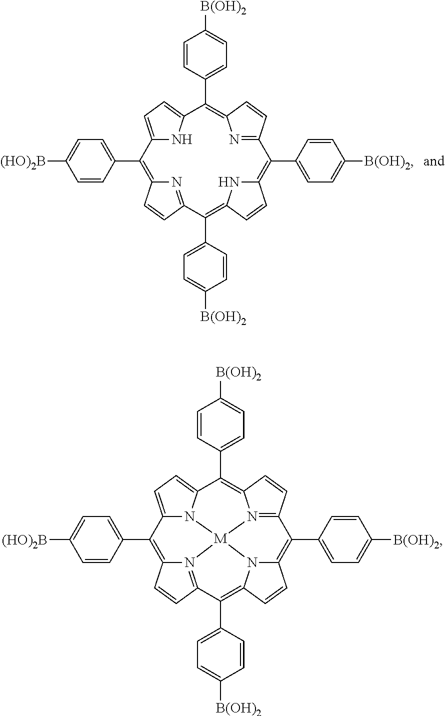

where M is a metal atom or metal ion, and the like.

The Lewis acid is any electron accepting material that catalyzes the formation of a boronate ester bond between a protected catechol subunit and multifunctional linker. An example of suitable of a Lewis acids include, but are not limited to, boron trifluoride (or its various ether, sulfide, amine, or other adducts), and the like. The Lewis acid can be added in solid, liquid (e.g., in solution), or gaseous form.

Any solvent in which the reactants (e.g., protected catechol, linker and Lewis acid) have sufficient solubility and reactivity can be used. Suitable solvents include, but are not limited to, toluene, alcohols (e.g., methanol), chlorinated hydrocarbons (e.g., 1,2-dichloroethane), 1,2-dichlorobenzene, tetrahydrofuran, anisole, dioxane, mestiylene, dimethylacetamide, and the like. Combinations of such solvents can also be used.

Reaction conditions/parameters can be important in preparing crystalline COFs. Examples of such conditions/parameters include, but are not limited to, reaction temperature, concentration of protected subunit, concentration of linker, concentration of Lewis acid, and the like. The determination of suitable reaction conditions is within the purview of one having skill in the art.

In an aspect, the present invention provides devices comprising at least one COF of the present invention. COFs can be incorporated in devices such as, for example, solar cells (e.g., bulk heterojunction/dye sensitized solar cells), flexible displays, lighting devices (e.g., light emitting diodes), RFID tags, sensors, photoreceptors, batteries, capacitors, and light emitting diodes. Other applications for COFs that might be synthesized by our method include materials capable of storing gases (e.g., H₂, CO₂, NH₃ and the like), separating different chemical species, heterogeneous catalysts, time-release or stimulus-responsive drug delivery systems, and the like.

### Example 1

In this example a general method for the synthesis of boronate ester-linked COFs that avoids the direct use of insoluble and unstable polyfunctional catechol reactants is described. Using this method, two-dimensional networks of cofacially-stacked phthalocyanines (Pcs) have been prepared, strongly absorbing chromophores that have been employed in both bulk heterojunction and dye-sensitized solar cells, as well as for many other applications. The phthalocyanine COF forms an eclipsed two-dimensional square lattice as determined by powder x-ray diffraction, surface area analysis, and UV/Vis/Near IR and fluorescence spectroscopies. This material can be used in forming COF-based bulk heterojunctions featuring structurally precise and high surface area interfaces between complementary organic semiconductors.

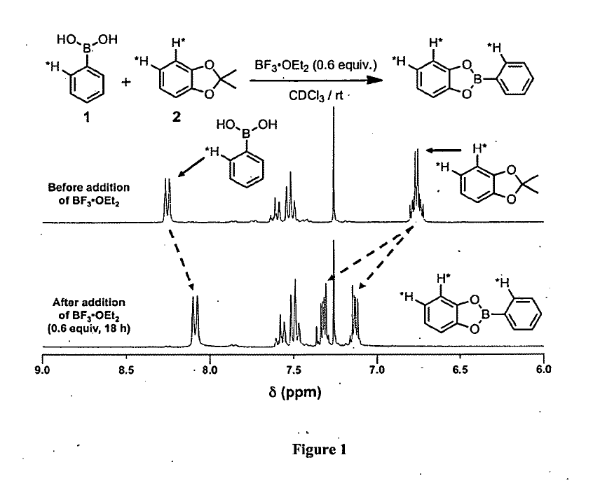

The direct formation of boronate esters from protected catechols presents an attractive alternative for COF synthesis because the protecting groups can decrease the compound's polarity, prevent autoxidation, and confer enhanced solubility. It was found (FIG. 1) that phenyl boronic acid 1 reacts cleanly with catechol acetonide 2 to form the corresponding catechol boronate ester in the presence of substoichiometric amounts of the Lewis acid BF₃.OEt₂. The reaction can take place over the course of a few hours at mM concentrations of starting materials in several ether and non-coordinating solvents at mild temperatures (20-85° C.), and does not require the rigorous exclusion of oxygen or water.

The phthalocyanine tetra(acetonide) 3 (FIG. 2) is a suitable tetrafunctional catechol equivalent for the formation of COFs under the BF₃—OEt₂-catalyzed boronate esterification conditions. Multigram quantities of 3 were obtained by modifying a previously reported synthetic procedure. Phthalocyanine 3 is moderately soluble in many organic solvents and stable under ambient conditions. In contrast, the corresponding octahydroxyphthalocyanine has been reported as a highly insoluble solid that must be stored under an inert atmosphere to prevent its oxidation. Pc-PBBA COF was synthesized by combining 3 (32 mg), 1,4-phenylenebisboronic acid (PBBA, 18.5 mg), and BF₃.OEt₂ (0.015 mL) in a 1:1 mixture of mesitylene and 1,2-dichloroethane in a flame-sealed glass reaction vessel. The sealed tube was placed in a 120° C. oven for six days. The resulting green precipitate was collected by filtration and washed with anhydrous MeCN to isolate Pc-PBBA COF in 48% yield. The isolated COF displays excellent thermal stability to 500° C. as determined by thermogravimetric analysis (TGA).

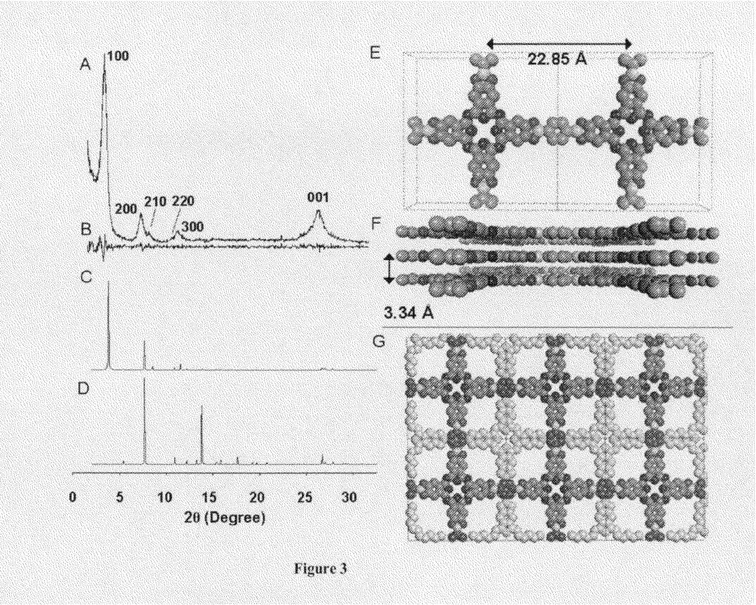

The powder X-ray diffraction (PXRD) pattern of Pc-PBBA COF (FIG. 3A, black) indicates that it is a crystalline material consistent with the long-range structure depicted in FIG. 2. The most intense peak at 2θ=3.840 corresponds to the (100) and (010) diffractions of the square lattice. The minor diffraction peaks at 7.68°, 8.52°, 11.56°, and 26.64° correspond to the (200), (210), (300), and (001) diffractions, respectively. None of the observed peaks correspond to the phthalocyanine or the PBBA starting materials (see FIG. 21). Pawley refinement of the observed PXRD pattern profile using the Reflex Plus module of the Materials Studio ver. 4.4 suite of programs (FIG. 3A) produced unit cell parameters a=b=22.85 Å and c=3.34 Å (FIGS. 3E and F) and confirmed the assignment of the observed reflections. The refined profile matches the observed pattern very well, with profile-fitting factors converging to wRₚ=9.72% and Rₚ=6.46%. The difference plot (FIG. 3B) also indicates a good fit with the only deviations appearing in the very low angle region, where background interference is greatest.

Simulation of the PXRD pattern of the eclipsed 2D Pc-PBBA lattice (FIG. 3C) showed good agreement with the experimental data. A unit cell precursor consisting of a phthalocyanine macrocycle functionalized with phenylboronate esters at each of the four termini (FIG. 3E) was constructed and its geometry optimized (hydrogen atoms were omitted). A tetragonal crystal of D₄ₕ (P4/mmm) symmetry was then generated with initial lattice parameters a and b corresponding to the distance between the centroids of phenylene units on opposite sides of the cell (ca. 23 Å). The interlayer spacing c was initially set as 3.33 Å, the π-π stacking distance in boron nitride. After reoptimizing the crystal geometry, the resulting simulated powder diffraction pattern matched the experimental peak positions and intensities quite well. The calculated lattice parameters (a=b=22.96 Å, c=3.34 Å) from this model were also quite close to the measured and refined parameters (a=b=22.85 Å, c=3.34 Å).

An alternative staggered 2D arrangement (FIG. 3G) in which the phthalocyanine units of adjacent sheets are horizontally offset by a distance of a/2 and b/2 was also considered. The simulated PXRD pattern for this arrangement (FIG. 3D) does not match the experimental data. The formation of the eclipsed structure can be attributed to the strong tendency for phthalocyanine units to form cofacial aggregates reinforced by stabilizing B—O interactions between adjacent layers.

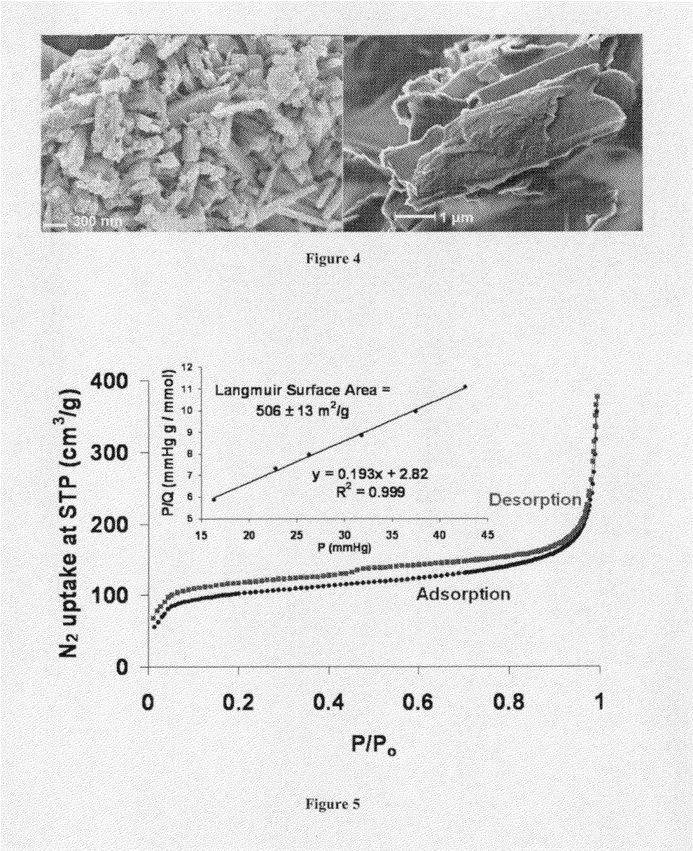

Two distinct crystal morphologies were observed by scanning electron microscopy (SEM) imaging of Pc-PBBA COF: one with a striated rectangular prism shape averaging approximately 1 μm in length and 200-300 nm in thickness and one of flattened irregular plates 2-4 μm long (see FIG. 4) The presence of these two phases may account for line broadening in the PXRD pattern, and could be the result of differing nucleation or growth environments in the reaction vessel.

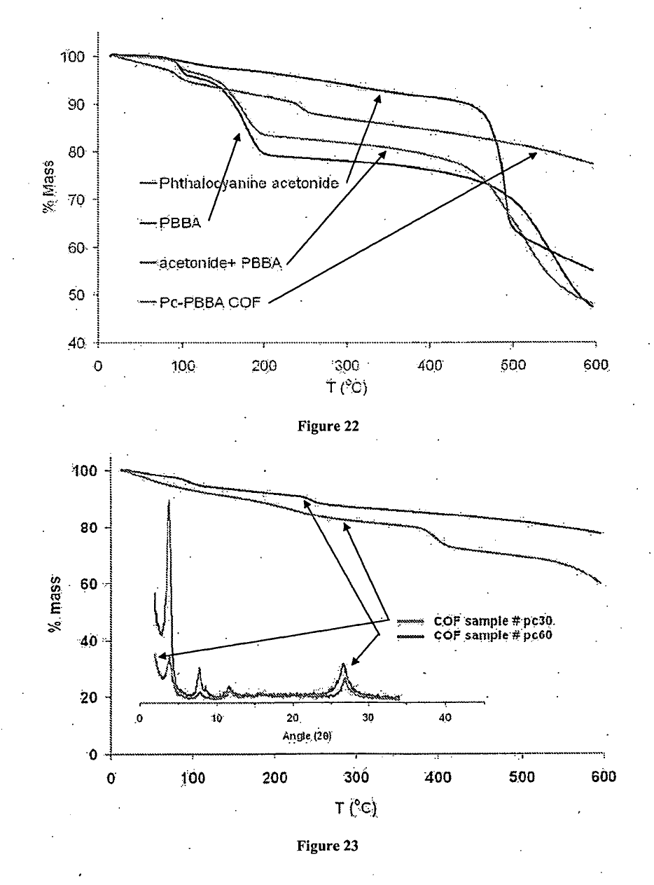

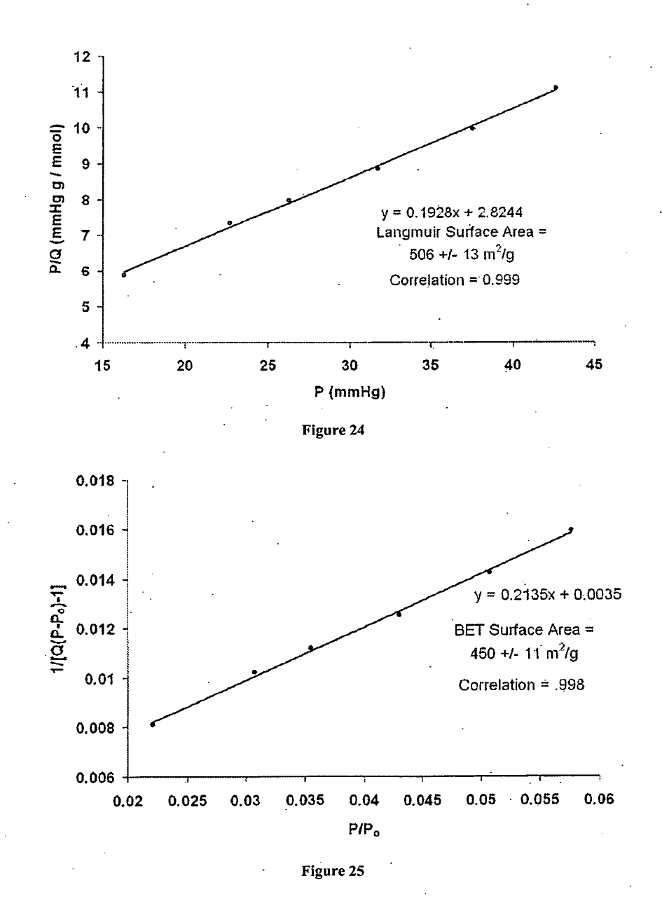

The Fourier transform infrared (FTIR) spectrum of Pc-PBBA COF obtained in attenuated total reflectance (ATR) mode indicates the formation of boronate ester rings through the strong B—O stretch at 1328 cm⁻¹ (see FIG. 11). An analogous band at 1344 cm⁻¹ appears in the spectrum of the PBBA starting material, though the two spectra are otherwise quite different. The hydroxyl bands of the COF are greatly attenuated relative to the starting materials, consistent with free hydroxyl groups at the edges of the crystallites or at defects. The phthalocyanine acetonide 3 shares many IR absorbances with the Pc-PBBA COF material, though the methyl C—H stretches from the acetonide protecting groups are notably absent from the COF spectrum. An FTIR spectrum of a crude sample of octahydroxyphthalocyanine was obtained by treating 3 with BF₃—OEt₂ in the absence of PBBA. Its FTIR spectrum is distinct from that of the COF (see FIG. 22). These obseivations provide strong evidence for the formation of the boronate ester-linked material.

The porosity and surface area of the material was measured by N₂ gas adsorption. An adsorption isotherm between 0 and 1 bar was generated after evacuation under continuous vacuum for 12 hours at 180° C. (FIG. 5). A sharp initial uptake at low pressures was observed as the small pores were filled, followed by a more gradual uptake over the remainder of the pressure range. Desorption occurred with a small hysteresis at about P/P₀=0.5. The Langmuir surface area model was applied to the P/P₀=0.02-0.06 (16 to 43 mm Hg) region of the isotherm where initial adsorption is most linear. The calculated Langmuir surface area from these data is 506 m²/g, which is slightly lower relative to other reported COFs, but still well within the values of other micro- and mesoporous materials such as zeolites and several metal-organic frameworks (MOFs). The increased density of a square lattice combined with the relatively small phenylene linker unit results in a lower surface area material. This trend has been observed in series of COFs with gradually increasing pore size.

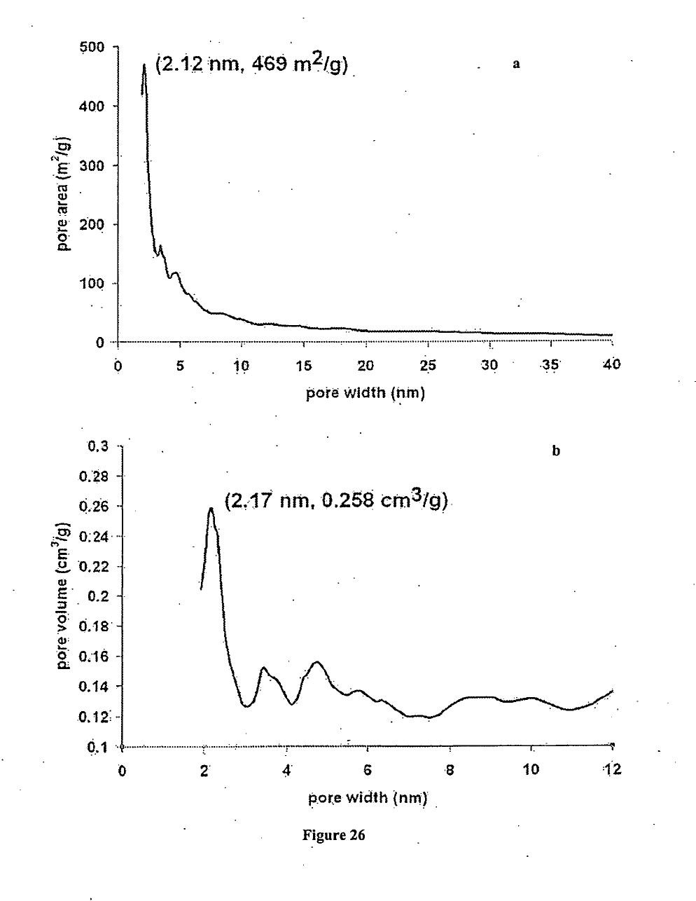

The Barrett-Joyner-Halenda (BJH) adsorption/desorption model was used to assess the pore size and volume distributions (see FIG. 26). Pore distribution plots reveal a maximum pore area of 469 m²/g at a width of 2.12 nm and a maximum pore volume of 0.258 cm³/g at a width of 2.17 nm. Peaks at larger pore sizes likely result from uptake in structural defects or slipped sheets along the micropore walls. The BJH model is most appropriate for mesoporous materials with pore sizes between 2 and 300 nm. Pc-PBBA COF has a predicted pore width of approximately 2 nm, which is at the lower limit. Even with this limitation, the pore data match predictions from Materials Studio reasonably well.

Phthalocyanines strongly absorb visible light and are thus deep blue or green compounds depending on the identity (or absence) of a metal ion coordinated to the four central nitrogen atoms. The electronic absorption spectra of dilute CH₂Cl₂ solutions of 3 (˜10⁻⁶ M) are typical of non-aggregated free base phthalocyanines. The sharp peaks at 653 and 691 nm located within the broad absorption band from 500-725 nm (Q-band) are hallmarks of monomeric phthalocyanine macrocycles. Diffuse reflectance spectra obtained from powders of both Pc-PBBA COF and 3 show a blue-shift of these maxima (11 nm for the COF and 66 nm for 3, respectively) consistent with the formation of cofacially stacked H-aggregates, as well as broadening of the Q-band into the NIR. Similar blue shifts and spectral band broadening have been observed for solutions of aggregated phthalocyanines and in liquid crystalline phases of cofacially-aligned phthalocyanine discotic mesogens. The COF spectrum is red-shifted from 3 by a small amount, which likely arises from differences in aggregation geometry as well as the electron withdrawing nature of the boronate esters relative to the acetonide functionalities. The changes in absorbance properties exhibited by Pc-PBBA COF, particularly the broadening of the absorbance to enhance absorption in the 450-600 nm region as well as the tailing into the near infrared, make these materials promising candidates for solar energy collection.

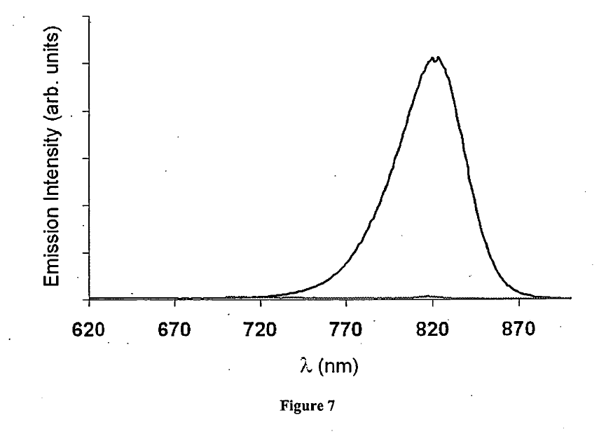

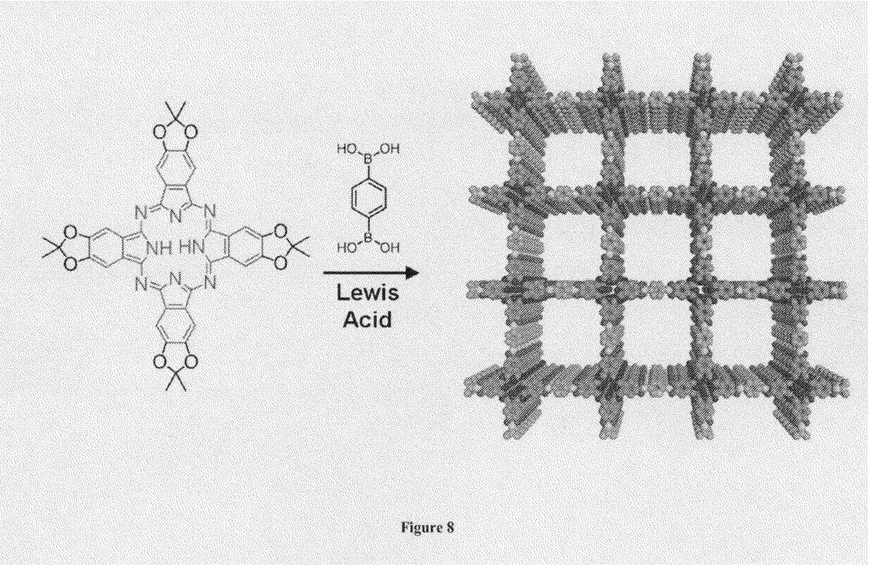

Photoluminescence measurements of Pc-PBBA COF are also suggestive of an H-aggregated structure. CH₂Cl₂ solutions of 3 fluoresce strongly with a small Stokes shift (17 nm, λₑₘ=708 nm) typical of monomeric phthalocyanines of similar structure. The solid samples of Pc-PBBA COF are nonemissive, as observed for other phthalocyanine H-aggregates (FIG. 7). These results can also be understood by exciton theory. 3 was expected to form nonemissive aggregates in the solid state but it was found that both powders and drop-cast films of 3 fluoresce very weakly at 820 nm. It is considered that the four acetonide groups distort the cofacial aggregates of 3, resulting in weakly allowed emission from a dimer or higher-order aggregate. This process is not observed in the more structurally precise COF. It should be noted that both the changes in absorption and emission of the phthalocyanine moieties observed in the COF materials strongly suggest cofacial stacking. Phthalocyanine J-aggregates (offset stacks) show red shifted absorption spectra and are emissive. Furthermore, disordered phthalocyanine-containing macroporous polymers that prevent phthalocyanine aggregation show absorption and emission behavior in the solid state similar to the solution behavior of 3.

A new Lewis acid-catalyzed protocol to synthesize boronate ester-linked covalent organic frameworks directly from acetonide-protected catechols has been demonstrated. This method greatly broadens the scope of catechol derivatives that may be incorporated into these materials. Using this method an eclipsed two-dimensional COF was prepared from a synthetically convenient phthalocyanine tetra(acetonide) precursor. The synthetic availability, structural precision, and robust nature of these materials make them excellent choices for well-ordered photovoltaic devices. The pores created by vertical stacking of the sheets present the opportunity to introduce a complementary organic semiconductor to obtain structurally precise bulk heterojunction composites.

### A. Materials.

All reagents were purchased from commercial sources and used without further purification. Phthalonitrile acetonide was prepared via a previously reported procedure. 1-pentanol, mesitylene and 1,2-dichloroethane were purchased from commercial sources and used without further purification. Other solvents were purchased from commercial sources and purified using a custom-built alumina-column based solvent purification system.

### Instrumentation.

Infrared spectra were recorded on a Thermo Nicolet iS10 with a diamond ATR attachment and are uncorrected.

UV/Vis absorbance spectra were recorded on a Cary 5000 UV-Vis-NIR spectrophotometer with a mercury lamp in either dichloromethane solution or as solids using a praying mantis diffuse reflectance accessory. Emission and excitation spectra were recorded on a Horiba Jobin Yvon Fluorolog-3 fluorescence spectrophotometer equipped with a 450 W Xe lamp, double excitation and double emission monochromators, a digital photon-counting photomultiplier and a secondary InGaAs detector for the NIR range. Correction for variations in lamp intensity over time and wavelength was achieved with a solid-state silicon photodiode as the reference. The spectra were further corrected for variations in photomultiplier response over wavelength and for the path difference between the sample and the reference by multiplication with emission correction curves generated on the instrument. Solid samples were mounted between quartz slides and mounted on a solid sample holder, and emission was observed using a front face detection accessory.

X-ray diffraction patterns were recorded on a Scintag Theta-Theta Powder X-Ray Diffractometer in reflectance Bragg-Brentano geometry employing Cu Kα line focused radiation at 2200 W (45 kV, 40 mA) power and equipped with a Ge crystal detector fitted with a 0.3 mm radiation entrance slit. Samples were mounted on zero background sample holders by dropping powders from a wide-blade spatula and then leveling the sample surface with a glass microscope slide. No sample grinding or sieving was used prior to analysis. Samples were observed using a 0.04° 20 step scan from 2.0-34° with an exposure time of 0.4 s per step. No peaks could be resolved from the baseline for 20>34° data and was therefore not considered for further analysis.

Thermogravimetric analysis from 20-600° C. was carried out on a TA Instruments Q500 Thermogravimetric Analyzer in nitrogen atmosphere using a 10° C./min ramp without equilibration delay.

Mass spectra were obtained on a Waters MALDI micro MX MALDI-TOF mass spectrometer using positive ionization and a reflectron detector. MALDI samples were prepared by wet deposition of a 10% analyte/dithranol matrix solution onto a metallic sample plate and air dried before loading into the instrument.

Surface area measurements were conducted on a Micromeritics ASAP 2020 Accelerated Surface Area and Porosimetry Analyzer using ca. 20 mg samples degassed at 180° C. for 12 hours. Nitrogen isotherms were generated by incremental exposure to ultra high purity nitrogen up to ca. 1 atm over 28-hour periods in a liquid nitrogen (77K) bath, and surface parameters were determined using Langmuir, BET and BJH adsorption models included in the instrument software (Micromeritics ASAP 2020 V1.05).

SEM images were obtained on a LEO 1550 FESEM at 5 keV. Materials were deposited onto a sticky carbon surface on a flat aluminum platform sample holder and vacuum-degassed at 65° C. for 1 hour. No metal sputtering of the sample was necessary.

NMR spectra were recorded on a Varian Mercury-300 300 MHz spectrometer using a standard ¹H/X Z-PFG probe at ambient temperature with a 20 Hz sample spin rate.

X-ray photoelectron spectroscopy was performed on a Surface Science Instruments Model SSX-100 using monochromated Al Kα radiation (1486.6 eV) and a 5 keV Argon ion beam for sample cleaning.

### B. Synthetic Procedures.

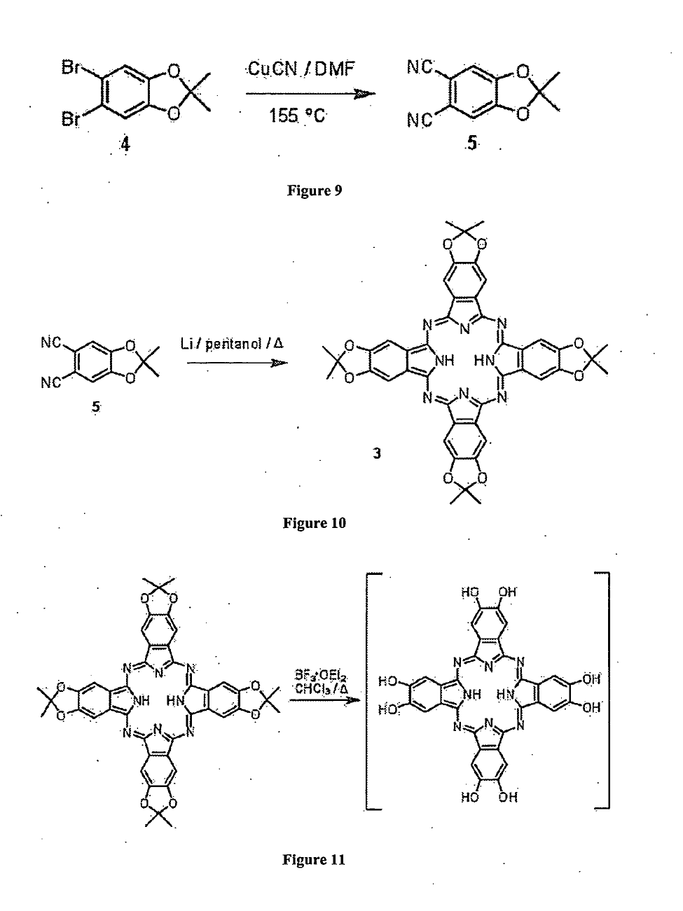

Synthesis of phthalonitrile acetonide 5 was prepared by a previously reported method and is shown in FIG. 9. Its ¹H NMR spectrum matched that reported previously.

Synthesis of phthalocyanine acetonide 3 is shown in FIG. 10 (Scheme S2). Phthalonitrile (1.20 g, 5.99 mmol) was dissolved in 20 mL 1-pentanol and lithium metal granules (420 mg, 60 mmol) were added at room temperature with vigorous stirring. The mixture was heated to reflux (140° C.) for five hours under a N₂ atmosphere. During this time, the reaction mixture became very dark green. The mixture was cooled to room temperature, and 20 mL glacial acetic acid was added with stirring. After 30 minutes, the solution was concentrated under vacuum to remove excess 1-pentanol. The resulting green residue was dissolved in chloroform and methanol (15:1, 100 mL) and washed with brine (3×100 mL) and H₂O (1×100 mL). The dark green organic layer was dried with MgSO₄ and concentrated to ca. 50 mL. The solution was triturated with 200 mL of hexanes, causing a dark precipitate to form. The green precipitate was isolated from the brown supernatant by centrifugation. The trituration and centrifugation steps were repeated to provide the phthalocyanine tetraacetonide 3 (620 mg, 52%) as a dark indigo-blue solid. MALDI-MS 802.20 (M). IR (powder, ATR) 2990, 2921, 2850, 1764, 1716, 1682, 1603, 1474, 1447, 1409, 1386, 1376, 1250, 1214, 1073, 1026, 1002, 979, 852, 812, 785, 737, 714. UV-Vis [λ/nm (log ε/M⁻¹ cm⁻¹), 2.08 μM in CH₂Cl₂] 691 (5.09), 653 (5.02), 638 (4.68, she), 592 (4.34), 425 (4,53), 347 (4,89(, 294 (4.76). UV-Vis (powder, praying mantis DRA), 609, 396, 331, 289. Anal. Cald for C₄₄H₃₄N₈O₈: C, 65.83; H, 4,27; N, 13.96. Found: C, 64.66; H, 3.91; N, 13.10.

The MALDI MS and UV/Vis absorption spectra of 3 match those reported previously. The phthalocyanine acetonide was not able to be characterized by ¹H NMR, presumably due to its aggregation. Instead, the free base (10 mg, 0.012 mmol) was converted to the Zn derivative by stirring 3 in 10 mL DMF for 2 days at 65° C. with an excess of Zn(OAc)₂ and anhydrous K₂CO₃. Complete metalation was confirmed by MALDI-MS and UV-Vis absorption. The mixture was filtered, concentrated in vacuo, and dried under high vacuum at 100° C. overnight to remove solvent contaminants. The resulting green solid (4 mg) was dissolved in a mixture of CDCl₃ with 1% pyridine-d₅ for NMR analysis. ¹H NMR (300 MHz, CDCl₃/pyridine-d₅ 99:1) δ 8.61 (s, 8H), 1.00 (s, 24H); MALDI-MS 863.98 (M⁺). IR (solid, ATR) 2955, 2919, 2850, 1717, 1594, 1490, 1461, 1421, 1386, 1319, 1278, 1101, 1075, 1054, 1025, 981, 925, 852, 833, 802, 744. UV-Vis [λ/nm (log ε/M⁻¹ cm⁻¹), 3.47 μM in CH₂Cl₂] 667 (5.12), 641 (4.36, sh), 602 (4.30), 419 (4.15), 347 (4.66), 292 (4.62). The MALDI MS and absorption spectra also match those reported previously.

Deprotection of 3 is shown in FIG. 11 (Scheme S3). Preparation of Crude octahydroxyphthalocyanine. Phthalocyanine acetonide 3 was weighed into a 20-mL screw-cap scintillation vial, dissolved in chloroform, and excess boron trifluoride etherate was added via micropipette. The dark mixture was stirred at 65° C. for two days, then concentrated in vacuo and dried under high vacuum to yield a black solid that was insoluble in chloroform. MALDI-MS 642. 19 (M⁺). IR (powder, ATR) 3587, 3355, 3273, 1602, 1480, 1374, 1331, 1292, 1174, 1018, 869, 853, 799, 714, 668.

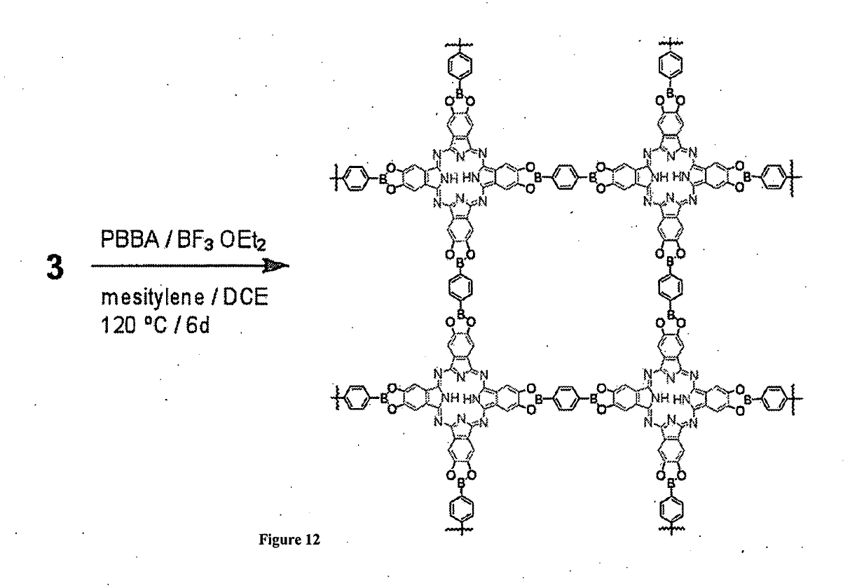

Synthesis of Pc-PBBA COF is shown in FIG. 12 (Scheme S4). Pc-PBBA COF. Phthalocyanine acetonide 3 (32 mg, 0.040 mmol) and 1,4-phenylenebisboronic acid (PBBA, 18.5 mg, 0.112 mmol) were weighed into a 1-dram screw-cap vial and suspended in a mixture of mesitylene and 1,2-dichloroethane (1:1, 1.5 mL). The dark blue mixture was sonicated for 15 minutes. Boron trifluoride etherate (15 μL, 0.12 mmol) was added dropwise via micropipette, and the mixture was sonicated another 15 minutes. The dark heterogeneous mixture was transferred via glass pipet to a pre-scored Kimble/Kontes trimmed-stem KIMAX-51 borosilicate glass ampoule (5 mL, body length 37 mm, outer diameter 16.75 mm, neck length 51 mm) and flash frozen in a liquid nitrogen bath. The ampoule neck was flame-sealed in air using a propane torch, reducing the total length by 20-30 mm. Upon warming to room temperature, the suspension was placed in a gravity convection oven at 120° C. and left undisturbed for 6 days. Uniform heating of the ampoule was found to be critical, as partial submersion in an oil bath or hot plate reaction well did not produce COFs. The reaction was cooled to room temperature, the ampoule was broken at the scored neck, and the dark mixture was poured onto a Hirsch filter funnel with a 15 mm diameter filtration surface and qualitative filter paper (medium porosity) and vacuum filtered. The dark solid was washed with 4 mL anhydrous acetonitrile and thoroughly air dried. Upon drying the material became very dark green. The material was scraped into a 1-dram screw-cap vial, treated with 3 mL anhydrous acetonitrile and let settle overnight, then refiltered to dryness to yield Pc-PBBA COF as a dark green solid (16 mg, 48%). Brief (ca. 10 minutes) drying under high vacuum was followed by characterization by powder x-ray diffraction. IR (powder, ATR) 3272, 1605, 1523, 1469, 1439, 1373, 1328, 1272, 1187, 1079, 1018, 866, 849, 810, 739, 709, 653. PXRD [2θ (relative intensity)] 3.84 (100), 7.76 (17), 8.56 (8), 11.68 (8), 26.52 (19), 26.64 (19). UV-Vis (powder, praying mantis DRA), 671, 325, 293. Anal. Calcd for (C₁₁H₅BN₂O₂)ₙ: C, 63.52; H, 2.42; N, 13.47. Found: C, 53.54; H, 2.41; N, 11.02. It has been noted that elemental analysis of boronate COFs typically give lowered carbon values from the formation of non-combustible boron carbide byproducts. Similar formation of boron nitride byproducts is anticipated, lowering the nitrogen value. The presence of boron was confirmed by a characteristic B is peak in the XPS with a binding energy of 192.839 eV and an abundance of 4.66% (calculated: 5.33% excluding hydrogens).

### C. MALDI-TOF MS of COF Precursors

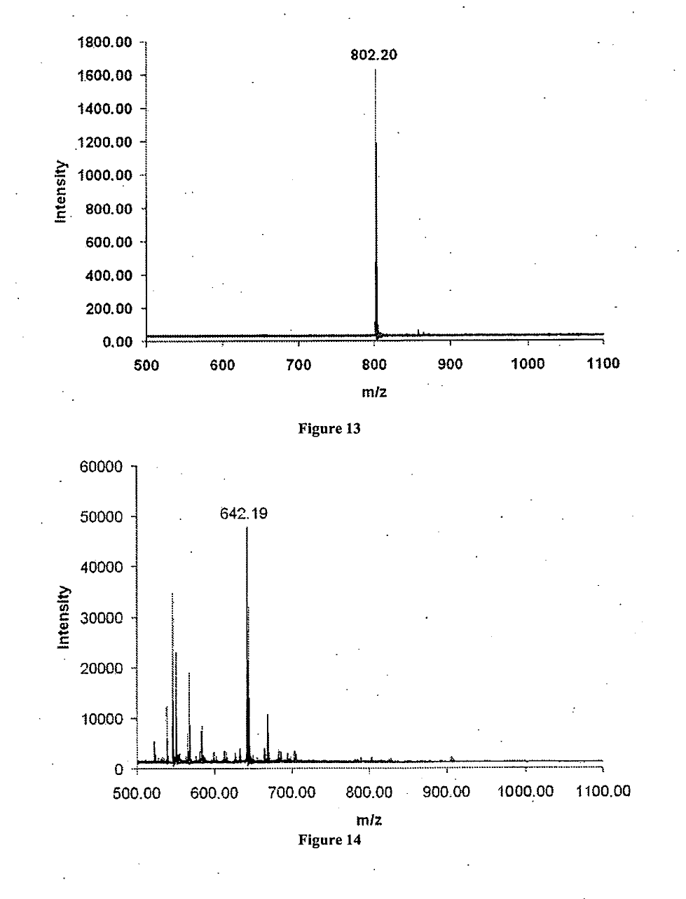

Characterization of COF precursors by mass spectrometry is shown in FIGS. 13-14.

### D. FT-IR Spectra.

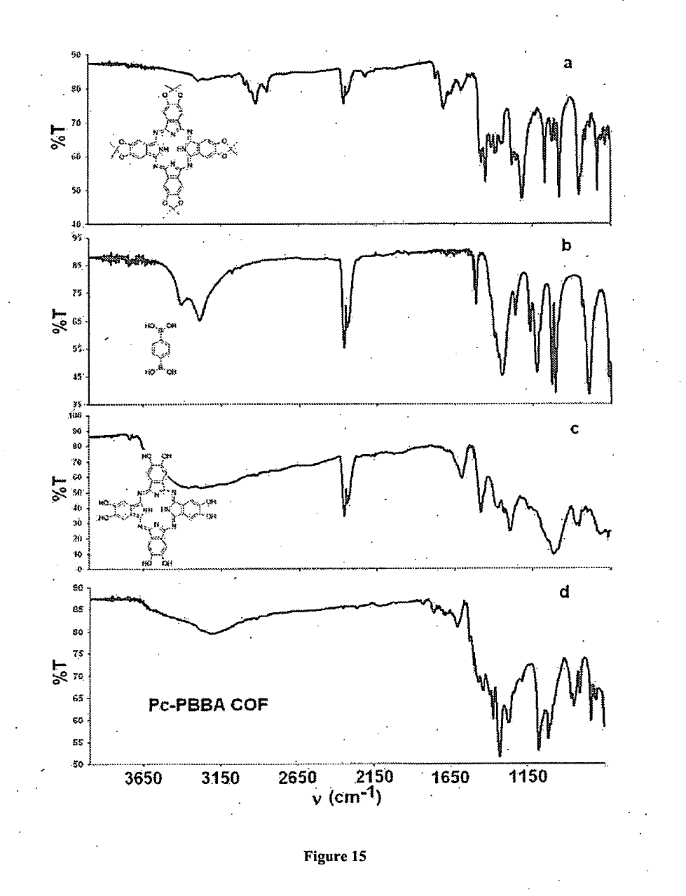

Characterization of COF precursors by mass spectrometry is shown in FIGS. 15-17.

### E. Simulation of the Pc-PBBA COF Structure.

Molecular modeling of the COF was carried out using the Materials Studio (ver.4.4) suite of programs by Accelrys. The unit cell precursor was defined as one phthalocyanine cycle bonded via four boronate ester linkages at the 2,3,9,10,16,17,23, and 24 positions to a benzene ring. The initial structure was geometry optimized using the MS Forcite molecular dynamics module (Universal force fields, Ewald summations), and the resultant distance between opposite benzene ring centroids in the structure was used as the a and b lattice parameters in a tetragonal D₄ₜₕ crystal (hydrogens omitted for calculation). The interlayer spacing c was initially chosen as 3.33 Å and the crystal structure was geometry optimized using Forcite. The MS Reflex Plus module was then used to calculated the expected PXRD pattern, which matched the experimentally observed pattern closely in both peak position and intensity (line broadening from crystallite size was not calculated). The observed diffraction pattern was subjected to Pawley refinement wherein peak profile and line shape parameters were refined using the Pseudo-Voigt peak shape function and asymmetry was corrected using the Berar-Baldinozzi function.⁵ The refinement was applied to the calculated lattice, producing the refined PXRD profile with lattice parameters a=b=22.85 Å and c=3.34 Å. wRₚ and Rₚ values converged to 9.72% and 6.46%, respectively. Overlay of the observed and refined profiles shows good correlation (Figure S8). The difference plot indicates the region of greatest deviation to be in the very low angle domain where background interference is greatest.

TABLE 1
Fractional atomic coordinates for unit cell of Pc-PBBA COF calculated
using the Materials Studio ver.4.4 modeling program after Pawley
refinement.
3D Tetragonal, D_{4 h}
(P4/mmm)
a = b = 22.85 Å, c = 3.34 Å

| atom | x | y | z |
|---|---|---|---|
| C1 | 0.44785 | 0.03036 | 0.50000 |
| C2 | 0.50000 | 0.06042 | 0.50000 |
| C3 | 0.53088 | 0.21731 | 0.50000 |
| C4 | 0.43790 | 0.26901 | 0.50000 |
| C5 | 0.47061 | 0.32024 | 0.50000 |
| C6 | 0.44691 | 0.37752 | 0.50000 |
| O1 | 0.44691 | 0.16189 | 0.50000 |
| B1 | 0.50000 | 0.12750 | 0.50000 |
| N1 | 0.50000 | 0.41343 | 0.50000 |
| N2 | 0.39484 | 0.39484 | 0.50000 |

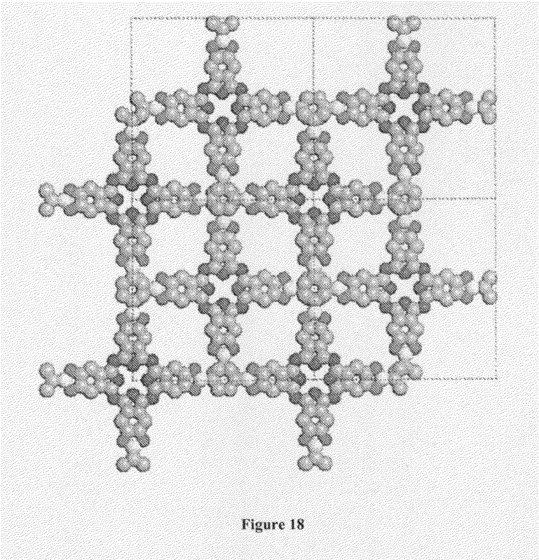

An alternative staggered COF arrangement (see FIG. 18) was examined wherein alternating stacked units were offset by a/2 and b/2. Comparison of the calculated PXRD pattern from this structure to the observed pattern shows no match, ruling out this type of packing arrangement. Comparison with the eclipsed arrangement's calculation, however, shows very good correlation.

### F. Powder X-Ray Diffraction Data

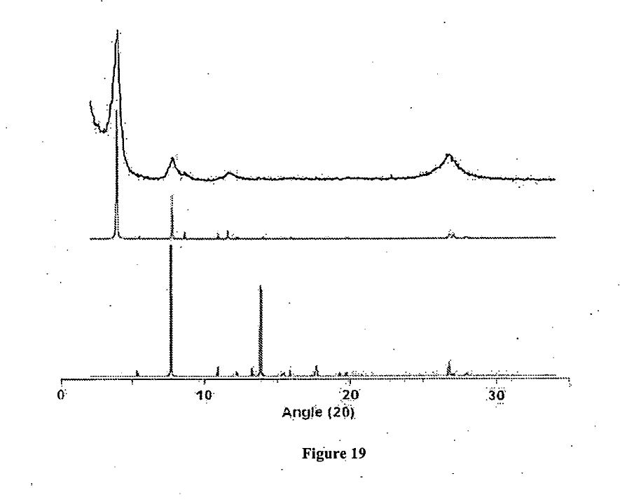

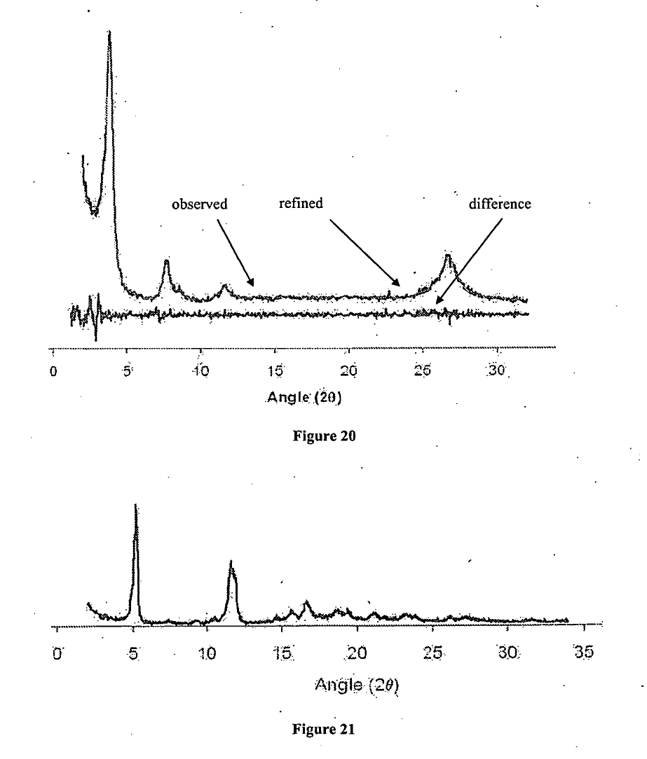

Characterization of COFs by X-ray Diffraction is shown in FIGS. 19-20. A PXRD pattern of the starting phthalocyanine acetonide 3 was obtained that displayed low-intensity peaks, one group of which (around 11.7°) seems to match roughly the peaks centered about the 300 reflection in the Pc-PBBA COF (see FIG. 21). Otherwise there is no correlation between starting material and product. Similarly, comparison with a published PXRD pattern of 1,4-phenylenebisboronic acid shows no similarity to the pattern of the COF.

### G. Thermogravimetric Analysis.

TGA traces of the COF along with the starting materials were obtained up to 600° C. using a linear 10° C./min ramp method (see FIG. 22). The COF shows impressive thermal stability up to at least 500° C., whereas the phthalocyanine acetonide and acid experience sharp losses of 25-30% mass around 450° C. The small losses around 100 and 250° C. in the COF could arise from desorption of solvent or unreacted starting materials within the pores or partial decomposition of acid moieties at the peripheries of crystallites.

More crystalline samples of the COF are more thermally stable, as evidenced by differences in the TGA traces of two samples of prepared Pc-PBBA COF (FIG. 21). The sample with superior PXRD characteristics (particularly the intensity of the 100 and 200 peaks, sec FIG. 23 inset) loses less mass at a given temperature compared to the less crystalline sample. The mass loss beginning around 370° C. is not observed in either starting material, so it may arise from decomposition of amorphous phthalocyanine-boronate ester networks rather than an ordered crystalline network. The two samples exhibited identical IR spectra.

### H. Surface Area Measurements.

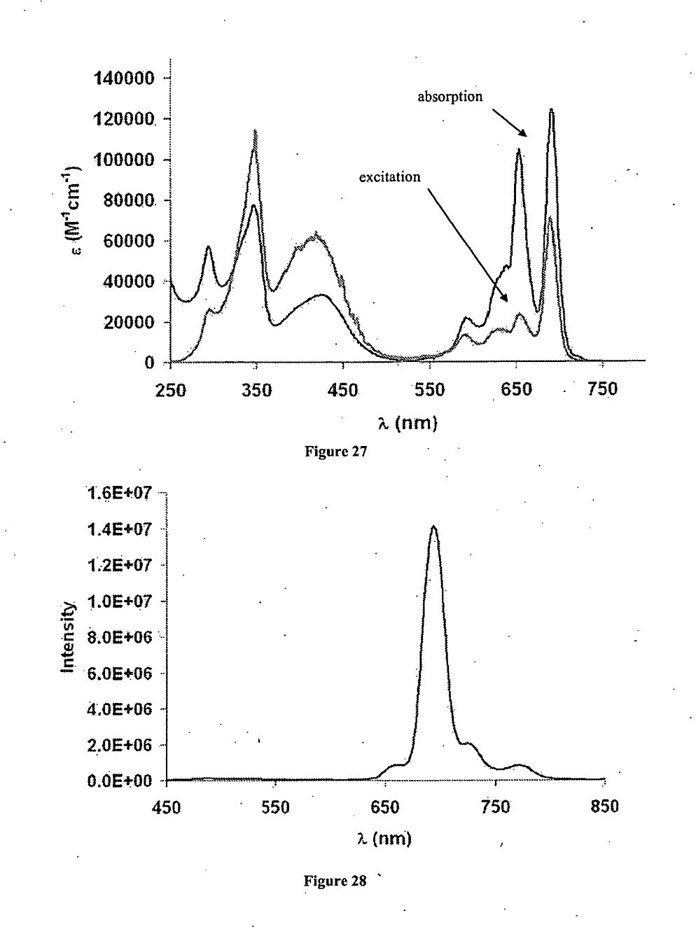

The porosity of the COFs was assessed by determining the surface are of the COFs. This is shown in FIGS. 5 and 25-27.

### I. Scanning Electron Micrographs of Pc-PBBA COF

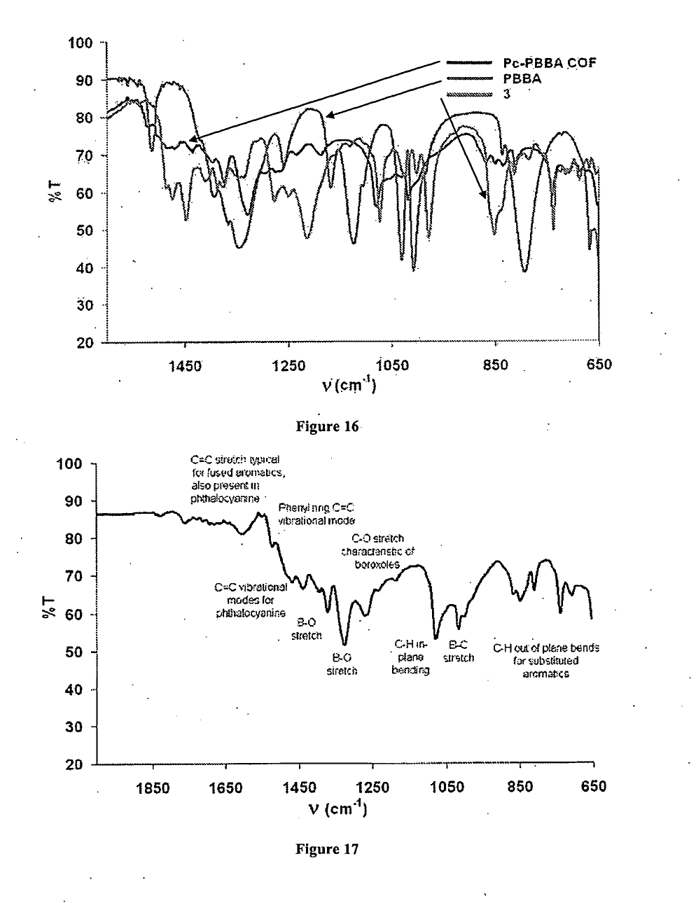

The COFs were characterized by scanning electron microscopy as shown in FIG. 16.

### J. UV-Vis-NIR and Photoluminescence Characterization

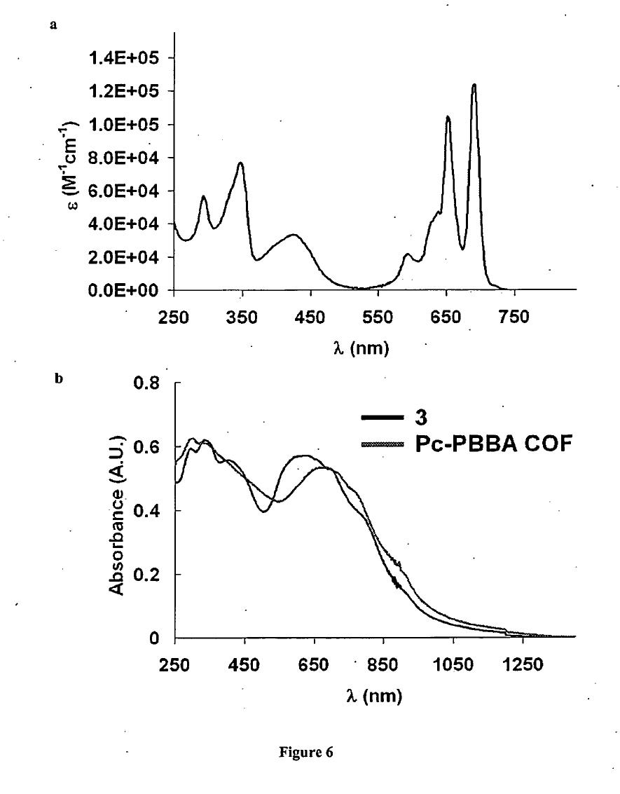

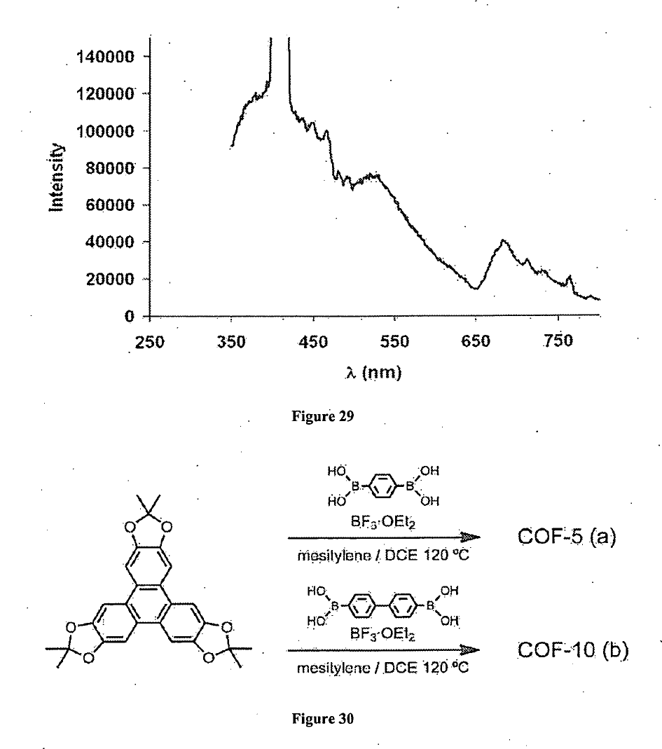

The absorption and emission characteristics of the COFs was characterized in FIGS. 6, 7 and 27-29.

### K. Characterization of COF-5 and COF-10 Prepared Using BF₃.OEt₂ Catalysis

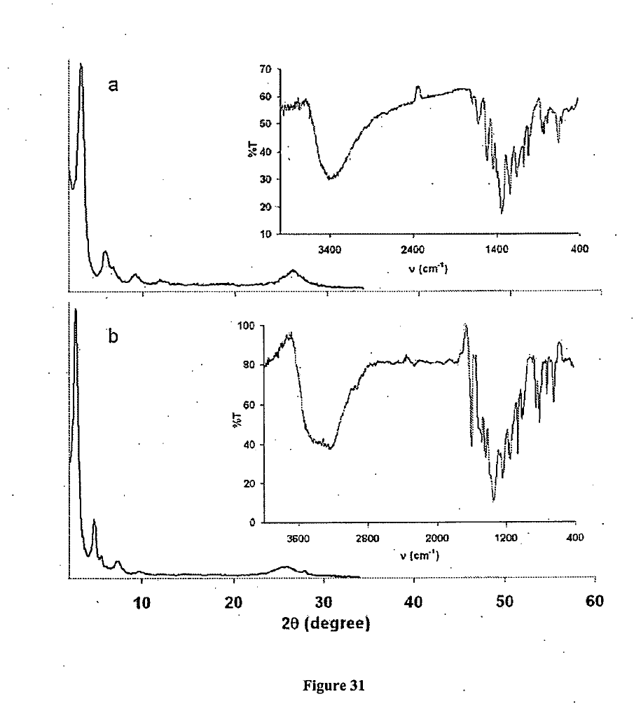

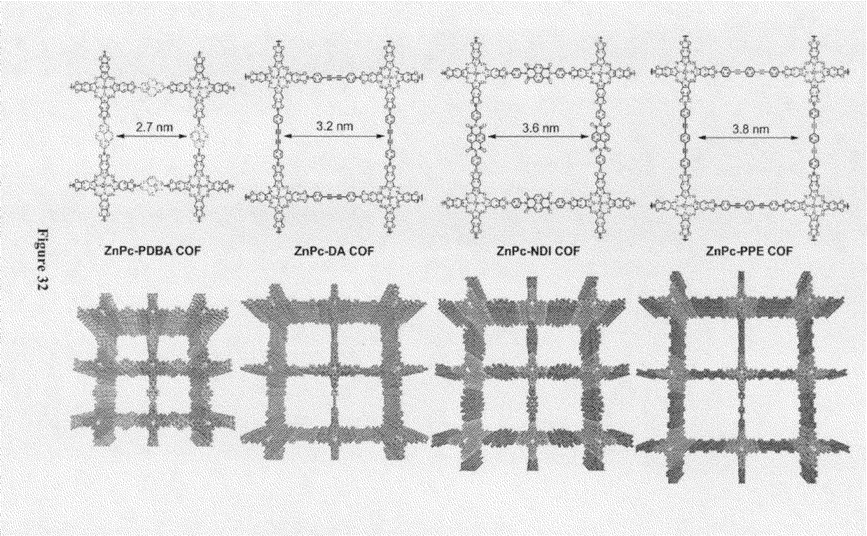

COF-5 and COF-10 were characterized by X-ray diffraction and FT-IR analysis (see FIG. 31).

### Example 2

### Examples of COFs

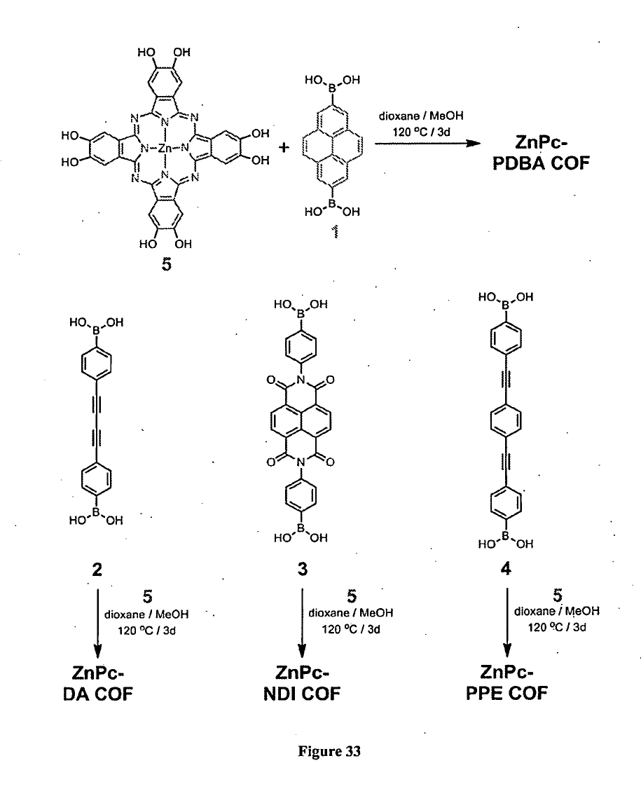

The structures of the COFs in this example are depicted in FIG. 32. ZnPc-PDBA COF. Pyrene diboronic acid 1 (17 mg, 0.059 mmol) and zinc octahydroxyphthalocyanine 5 (20 mg, 0.028 mmol) (see FIG. 33) were combined in a mixture of dioxane and methanol (2:1, 3 mL) and sonicated for 10 minutes. The dark green suspension was transferred to a 10 mL pre-scored long-necked glass ampoule, flash-frozen in a liquid nitrogen bath, and flame-sealed. The ampoule was placed in a 120° C. gravity convection oven for 96 hours, and the resulting free-flowing dark green powder was collected by filtration on a Hirsch funnel, washed with 1 mL anhydrous toluene and air-dried. Brief drying under vacuum was immediately followed by characterization by PXRD and IR. Isolated yield of ZnPc-PDBA COF 10 mg (52%). IR (powder, ATR) 3233, 1607, 1459, 1369, 1337, 1271, 1231, 1106, 1078, 1023, 902, 870, 824, 742, 714 cm⁻¹. PXRD [2θ (relative intensity)] 3.22 (100), 6.50 (24), 9.92 (5.6), 13.16 (4.3), 26.62 (6.4). UV-Vis (powder, praying mantis DRA) 711, 377 (sh), 336, 284 nm. Anal. Calcd. for (C₆₄H₂₄B₄N₈O₈Zn)ₙ: C, 67.34; H, 2.12; N, 9.82. Found: C, 63.65; H, 2.20; N, 10.34. It has been noted that elemental analysis of boronate COFs typically give lowered carbon values from the formation of non-combustible boron carbide byproducts. The presence of boron was confirmed by a characteristic B 1 s peak in the XPS with a binding energy of 190.8 eV. 27.

ZnPc-DA COF: Boronic acid 2 (17 mg, 0.059 mmol) and zinc octahydroxyphthalocyanine 5 (14 mg, 0.020 mmol) (see FIG. 33) were combined in a mixture of dioxane and methanol (3:1, 1.3 mL) and sonicated for 10 minutes. The dark green suspension was transferred to a 10 mL pre-scored long-necked glass ampoule, flash-frozen in a liquid nitrogen bath, and flame-sealed. The ampoule was placed in a 120° C. gravity convection oven for 72 hours, and the resulting free-flowing dark green powder was collected by filtration on a Hirsch funnel, washed with 1 mL anhydrous toluene and air-dried. Brief drying under vacuum was immediately followed by characterization by PXRD and IR. Isolated yield of ZnPc-DA COF 12 mg (53%). IR (powder, ATR) 3244, 1607, 1472, 1371, 1338, 1268, 1180, 1081, 1018, 869, 830, 742 cm⁻¹. PXRD [2θ (relative intensity)] 2.66 (100), 3.74 (4.7), 5.45 (15), 8.29 (5.9), 11.04 (1.9), 13.82 (1.3), 16.48 (0.86), 26.83 (2.2). UV-Vis (powder, praying mantis DRA) 713, 361 (sh), 301, 275 (sh) nm. Anal. Calcd for (C₆₄H₂₄B₄N₈O₈Zn): C, 67.34; H, 2.12; N, 9.82. Found: C, 54.15; H, 2.19; N, 9.68. It has been noted that elemental analysis of boronate COFs typically give lowered carbon values from the formation of non-combustible boron carbide byproducts. Similar formation of boron nitride byproducts is anticipated, possibly lowering the nitrogen value. The presence of boron was confirmed by a characteristic B is peak in the XPS with a binding energy of 191.7 eV.

ZnPc-NDI COF. Naphthalenediimide diboronic acid 3 (36 mg, 0.071 mmol) and zinc octahydroxyphthalocyanine 5 (17 mg, 0.024 mmol) (see FIG. 33) were combined in a mixture of dioxane and methanol (2:1, 3 mL) and sonicated for 10 minutes. The dark green suspension was transferred to a 10 mL pre-scored long-necked glass ampoule, flash-frozen in a liquid nitrogen bath, and flame-sealed. The ampoule was placed in a 120° C. gravity convection oven for 72 hours, and the resulting free-flowing dark green powder was collected by filtration on a Hirsch funnel, washed with 1 mL anhydrous toluene and air-dried. Brief drying under vacuum was immediately followed by characterization by PXRD and IR. Isolated yield of ZnPc-NDI COF 23 mg (60%). IR (powder, ATR) 3338, 1714, 1671, 1613, 1582, 1514, 1479, 1451, 1376, 1342, 1272, 1251, 1200, 1119, 1085, 1022, 984, 870, 835, 768, 742, 719 cm⁻¹. PXRD [2θ (relative intensity)] 2.44 (100), 5.00 (27), 7.52 (7.0), 12.52 (3.3), 26.92 (2.6). UV-Vis (powder, praying mantis DRA) 693, 333 (sh), 296 nm. Anal. Calcd for (C₈₄H₃₂B₄N₁₂O₁₆Zn)ₙ: C, 64.10; H, 2.05; N, 10.68. Found: C, 55.41; H, 2.56; N, 11.09. It has been noted that elemental analysis of boronate COFs typically give lowered carbon values from the formation of non-combustible boron carbide byproducts. The presence of boron was confirmed by a characteristic B 1 s peak in the XPS with a binding energy of 191.3 eV.

ZnPc-PPE COF. Diboronic acid 4 (22 mg, 0.060 mmol) and zinc octahydroxyphthalocyanine 5 (15 mg, 0.021 mmol) (see FIG. 33) were combined in a mixture of dioxane and methanol (5:1, 3 mL) and sonicated for 10 minutes. The dark green suspension was transferred to a 10 mL pre-scored long-necked glass ampoule, flash-frozen in a liquid nitrogen bath, and flame-sealed. The ampoule was placed in a 120° C. gravity convection oven for 84 hours, and the resulting free-flowing dark green powder was collected by filtration on a Hirsch funnel, washed with 1 mL anhydrous toluene and air-dried. Brief drying under vacuum was immediately followed by characterization by PXRD and IR. Isolated yield of ZnPc-PPE COF 20 mg (73%). IR (powder, ATR) 3060, 2930, 1711, 1605, 1472, 1395, 1351, 1270, 1227, 1187, 1042, 1015, 945, 915, 872, 830, 745, 704 cm⁻¹. PXRD [2θ (relative intensity)] 2.28 (100), 4.76 (18), 7.20 (6.9), 9.68 (3.4), 12.16 (2.5), 26.52 (2.3). UV-Vis (powder, praying mantis DRA) 693, 331, 308 nm. Anal. Calcd for (C₈₄H₃₂B₄N₁₂O₁₆Zn)ₙ: C, 70.56; H, 2.49; N, 8.66. Found: C, 59.20; H, 2.58; N, 8.70. It has been noted that elemental analysis of boronate COFs typically give lowered carbon values from the formation of non-combustible boron carbide byproducts. The presence of boron was confirmed by a characteristic B 1 s peak in the XPS with a binding energy of 191.3 eV.

While the invention has been particularly shown and described with reference to specific embodiments (some of which are preferred embodiments), it should be understood by those having skill in the art that various changes in form and detail may be made therein without departing from the spirit and scope of the present invention as disclosed herein.

1) A crystalline covalent organic framework (COF) comprising:
a plurality of phthalocyanine catechol subunits comprising a phthalocyanine moiety and at least two catechol moieties, and
a plurality of multifunctional linker groups comprising boron,
wherein a plurality of distinct phthalocyanine catechol subunits are bonded to at least one multifunctional linker by boronate ester bonds.

2) The crystalline COF of claim 1, wherein the phthalocyanine catechol subunit has the following structure:

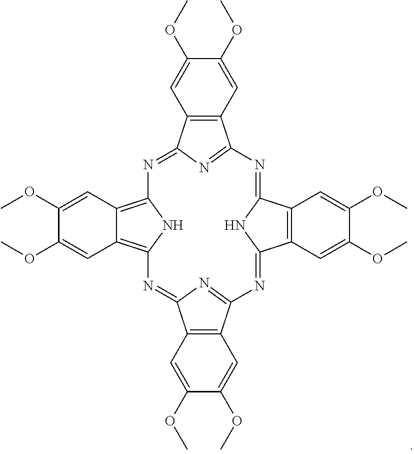

3) The crystalline COF of claim 1, wherein the subunit comprises a metal atom or metal ion.

4) The crystalline COF of claim 1, wherein the linking groups have the following structure: 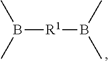
wherein R¹ is selected from an aryl group or non-aromatic polycyclic group.

5) The crystalline COF of claim 1, wherein the multifunctional linking group has a structure selected from: 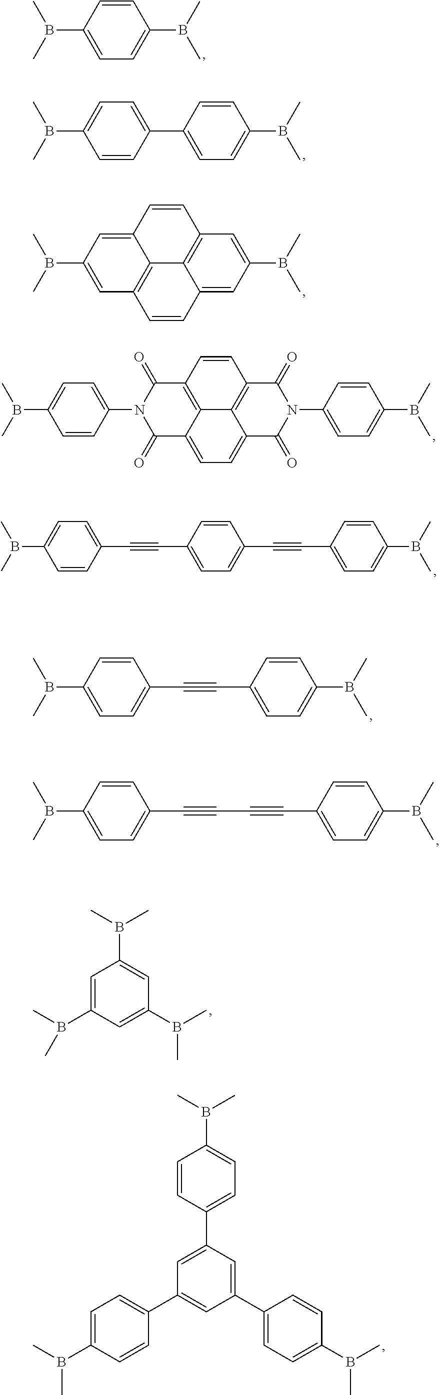 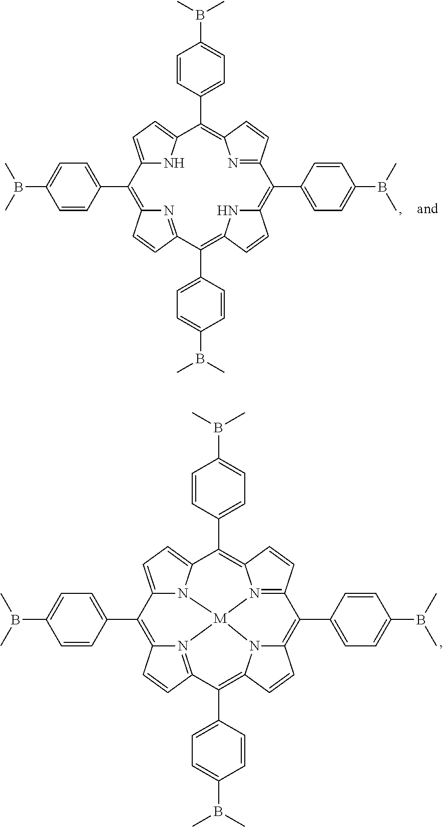
where M is a metal atom or metal ion.

6) The COF of claim 1, wherein the framework has pores having a diameter of 2 nm to 6 nm, wherein the pores run parallel to the stacked aromatic moieties

7) The COF of claim 1, wherein the framework is a crystallite, wherein the longest dimension of the crystallite is from 50 nm to 10 microns.

8) The COF of claim 1, wherein the framework is thermally stable at temperatures of from 20° C. to 500° C.

9) The COF of claim 1, wherein the framework absorbs light having a wavelength of 200 nm to 1500 nm.

10) A method for making a crystalline organic framework comprising: combining a protected subunit compound, a multifunctional linker comprising at least two boronic acid moieties, a Lewis acid, and a solvent at a suitable reaction temperature, wherein at least a plurality of covalent bonds are formed between at least one multifunctional linking compound and at least two different subunit compounds forming a two-dimensional or three-dimensional crystalline organic framework.

11) The method of claim 10, wherein the protected subunit compound has a structure selected from: 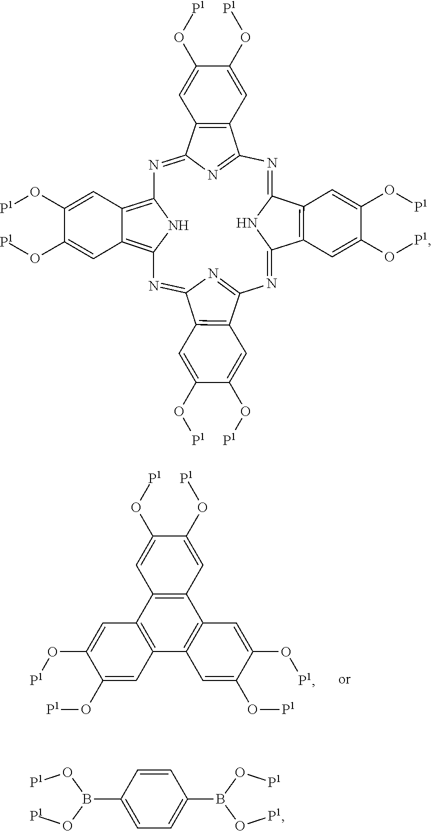
wherein P¹ is a protecting group or two P¹ groups form a protecting group.

12) The method of claim 10, wherein the multifunctional linker has the following formula:
H—O—B—R—B—O—H
wherein R¹ is an aryl group.

13) The method of claim 10, wherein the multifunctional linker is selected from:

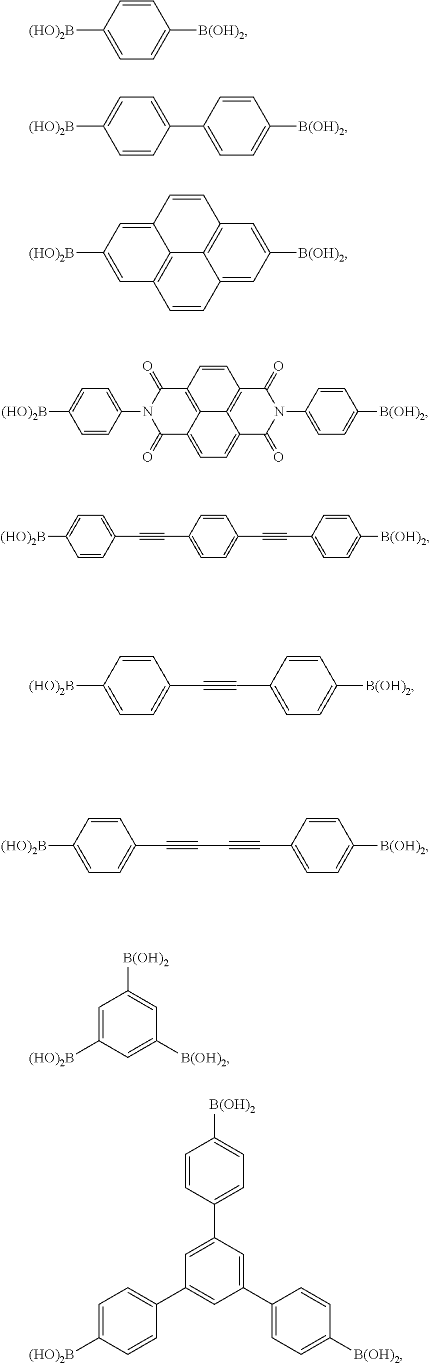

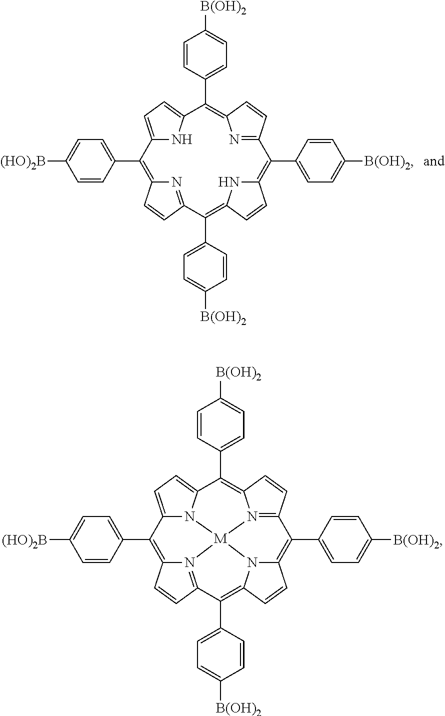

14) The method of claim 10, wherein the Lewis acid is BF₃.Et₂O.

15) A device selected from solar cells, flexible displays, lighting devices, RFID tags, sensors, photoreceptors, batteries, capacitors, gas storage devices, gas separation devices, comprising the crystalline covalent organic framework of claim 1 or a crystalline covalent framework made by the method of claim 10.
